(19) United States
(12) Patent Application Publication
(10) Pub. No.: US 2026/0262379 A1
(43) Pub. Date: Sep. 3, 2026

(54) ORGANIC ELECTROLUMINESCENT DEVICES

(71) Applicant: Universal Display Corporation, Ewing, NJ (US)

(72) Inventors: Michael FUSELLA, Princeton, NJ (US); Haridas MUNDOOR, Ewing, NJ (US); Nicholas J. THOMPSON, New Hope, PA (US)

(21) Appl. No.: 19/548,252

(22) Filed: Feb. 24, 2026

Related U.S. Application Data
(60) Provisional application No. 63/763,412, filed on Feb. 26, 2025.
(60) Provisional application No. 63/763,417, filed on Feb. 26, 2025.

(51) Int. Cl. H10K 50/854; H10K 102/00

(52) U.S. Cl. CPC H10K 50/854; H10K 2102/331

(57) ABSTRACT

Embodiments of the disclosed subject matter may provide a device may include a substrate, a first electrode, a second electrode, an organic layer disposed between the first electrode and the second electrode and the organic layer comprises an emitter material. The OLED may include an outcoupling layer having wavelength-sized or sub-wavelength sized features and the outcoupling layer may include a spacer layer and/or an overlayer. The spacer layer and/or the overlayer comprises a plurality of pores that are at least partially surrounded by a material. The OLED may include a reflector layer disposed on a second side of the organic layer, wherein the second side is opposite the first side, and wherein the reflector layer is configured such that at least 5% of light generated by the organic layer capable of being reflected by the reflector layer radiatively couples to the enhancement layer to form a photon-induced plasmon (PIP).

This application claims priority to U.S. Patent Application Ser. No. 63/763,412, filed Feb. 26, 2025, and U.S. Patent Application Ser. No. 63/763,417, filed Feb. 26, 2025, the entire contents of each are incorporated herein by reference.

### FIELD

The present invention relates to devices and techniques for fabricating organic emissive devices, such as organic light emitting diodes, that couple electrically-excited excitons into a plasmon polariton mode of an enhancement layer and harvest this additional photon energy that goes into the plasmon mode along with porous spacer layers/overlayers, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a device that is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting device (OLED) is also provided. The OLED can include a substrate, a first electrode disposed over the substrate, a second electrode disposed over the first electrode, and an organic layer disposed between the first electrode and the second electrode. According to an embodiment, the organic light emitting device is incorporated into one or more device selected from a consumer product, an electronic component module, and/or a lighting panel. The organic layer can include an emitter material.

According to an embodiment, the OLED can include an outcoupling layer having wavelength-sized or sub-wavelength sized features. The outcoupling layer can include a spacer layer and/or an overlayer. The spacer layer can be disposed next to the wavelength-sized or sub-wavelength sized features on a side facing the organic layer. The overlayer can be disposed next to the wavelength-sized or sub-wavelength sized features on a side opposite the organic layer. The spacer layer and/or the overlayer can include a plurality of pores that are at least partially surrounded by a material.

According to an embodiment, the organic layer is configured to generate one or more excited states. The OLED can include a plasmonic material supporting a plasmon polariton mode. The OLED can be configured to transfer at least 5% of energy from said one or more excited state to said plasmon polariton mode. The first electrode, the second electrode, or an additional layer disposed next to the first electrode or the second electrode can function as an enhancement layer comprising the plasmonic material. The enhancement layer can be disposed on a first side of the organic layer. The OLED can include a reflector layer disposed on a second side of the organic layer and the second side of the organic layer is opposite the first side of the organic layer. The reflector layer can be configured such that at least 5% of light generated by the organic layer capable of being reflected by the reflector layer radiatively couples to the enhancement layer to form a photon-induced plasmon (PIP).

The device may be a consumer electronic device, wherein the device may be a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, an optical communication device, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a plasmonic organic light emitting device.

FIG. 4 shows a device having a planar reflector layer and an optional diffuser layer on the same side of a substrate as an organic light emitting diode (OLED) stack according to an embodiment of the disclosed subject matter.

FIG. 5 shows a device having a corrugated reflector layer and an optional planarization layer on the same side of a substrate as the OLED stack according to an embodiment of the disclosed subject matter.

FIG. 6 shows a device having a planar reflector layer and an optional diffuser layer on the opposite side of a substrate as OLED stack according to an embodiment of the disclosed subject matter.

FIG. 7 shows a device having a planar reflector layer on the opposite side of a substrate as OLED stack and an optional diffuser layer on the same side of the substrate as the OLED stack according to an embodiment of the disclosed subject matter.

FIG. 8 shows a device having a corrugated reflector layer and an optional diffuser layer on the opposite side of a substrate as OLED stack according to an embodiment of the disclosed subject matter.

FIG. 9 shows an example device having a grating disposed on an enhancement layer and a reflector layer adjacent the substrate according to an embodiment of the disclosed subject matter.

FIG. 10A shows an example of offsetting a resonance of a reflector layer grating with the intrinsic emitter spectrum such that photons are reflected at oblique angles suitable for generating surface plasmons schematically according to an embodiment of the disclosed subject matter.

FIG. 10B shows an example of offsetting a resonance of a reflector layer grating with the intrinsic emitter spectrum such that photons are reflected at oblique angles suitable for generating surface plasmons using angle resolved electroluminescent data from an OLED according to an embodiment of the disclosed subject matter.

FIG. 11 shows a plot of example angles of incidence versus wavelength to generate a surface plasmon polariton according to embodiments of the disclosed subject matter.

FIG. 12 shows an example plasmonic organic light emitting diode (OLED) with an outcoupling structure having a porous spacer layer according to embodiments of the disclosed subject matter.

FIG. 13 shows three example arrangements of interactions between a pore at the surface of the spacer layer and a nanoparticle that may orient the nanoparticle, or to avoid reorientation, according to embodiments of the disclosed subject matter.

FIG. 14 shows an example plasmonic organic light emitting diode (OLED) with an outcoupling structure having a porous overlayer according to embodiments of the disclosed subject matter.

FIG. 15 shows an example plasmonic organic light emitting diode (OLED) with an outcoupling structure having a porous spacer layer and a porous overlayer according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

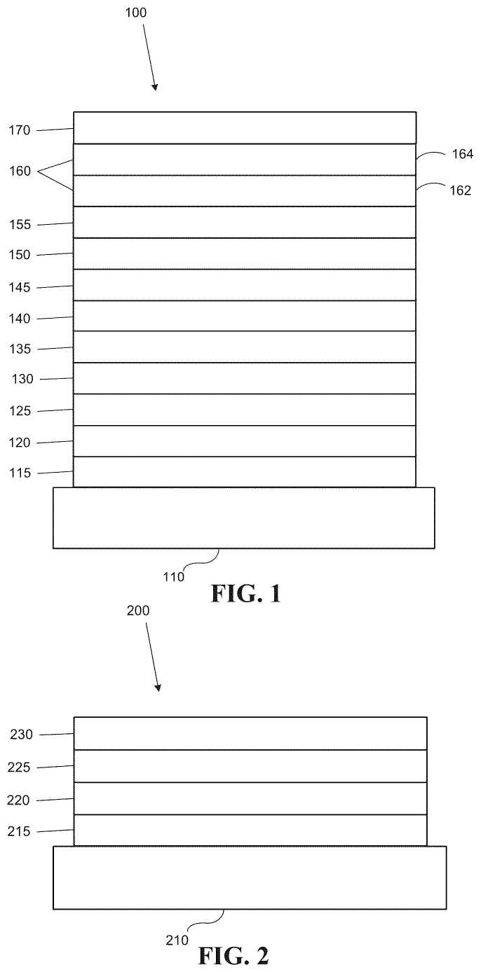

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

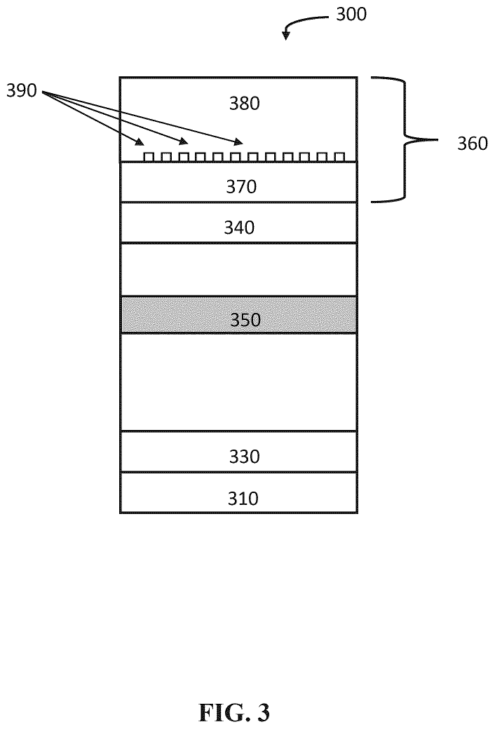

FIG. 3 illustrates an exemplary plasmonic OLED 300. It should be understood that the figures are provided for illustrative purposes only and are not necessarily drawn to scale. In some embodiments, device 300 may comprise a substrate 310, a first electrode 330, an organic layer 350 configured to generate excited states, a second electrode 340, an outcoupling layer 360 comprising a plurality of wavelength-sized or sub-wavelength sized features, such as nanoparticles 390, and optionally a spacer layer 370 and an overlayer 380. In some implementations, an enhancement layer comprising a plasmonic material may be incorporated into the first electrode, the second electrode, or provided as an additional layer disposed over the organic layer. The device may further include one or more additional functional layers commonly employed in conventional OLED described herein in FIGS. 1 and 2, such as HIL, HTL EBL, HBL, ETL, or EIL. Other optional layers typically utilized in OLED described herein, such as protective layers, barrier layers, or color alternating layers, may also be incorporated into the plasmonic OLED without departing from the scope of the present disclosure.

The simple layered structure illustrated in FIGS. 1-3 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1-3. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-3, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, the OLED can be configured into a plasmonic OLED. In such embodiments, the organic layer is configured to generate one or more excited states; the OLED comprises a plasmonic material supporting a plasmon polariton mode; and the OLED is configured to transfer at least 5% of energy from said one or more excited states to said plasmon polariton mode.

In some embodiments, the organic layer used to generate the one or more excited states can be an emissive layer as described herein. These excited states can originate from excited-state-forming materials, such as emitter materials disclosed herein, which may include phosphorescent, delayed fluorescent, doublet emitters, inverted singlet-triplet gap emitters, or non-delayed fluorescent compounds. Alternatively, excited states may be produced through the interaction of two components forming an exciplex, or via a sensitizer/acceptor pair within a sensitizing system, as described herein. In some embodiments, the organic layer may comprise one or more emitter materials, one or more host materials, components capable of forming an exciplex, and/or a combination of sensitizer and acceptor materials to establish a sensitizing system, each of which may be employed in the emissive layer of a conventional OLED. While the emissive layer in a conventional OLED is primarily designed to convert excited-state energy directly into photons, the emissive layer in a plasmonic OLED is instead configured to transfer the excited-state energy predominantly into the plasmon polariton mode.

In some embodiments, the plasmonic material is configured to support a plasmon polariton mode. In some embodiments, the plasmon polariton mode can be a surface plasmon polariton mode. In some embodiments, the first electrode, second electrode, or an additional layer disposed next to the first electrode or the second electrode functions as an enhancement layer comprising the plasmonic material. In some embodiments, the first electrode may be the anode and the second electrode may be the cathode. In some embodiments, the first electrode may be the cathode and the second electrode may be the anode. In some embodiments, the plasmonic material can be comprised of materials having a plasmon resonance, optically active metamaterials, or hyperbolic metamaterials. As used herein, a material having a plasmon resonance is a material in which the real part of the dielectric constant crosses zero in the visible or ultraviolet region of the electromagnetic spectrum. In some embodiments, the real part of the dielectric constant of the plasmonic material is less than zero in part of the ultra-violet, visible, or near infrared regions of the electromagnetic spectrum. In some embodiments, the plasmonic material includes at least one metal. In such embodiments the metal may include, but not limited to, at least one of Ag, Al, Au, Ir, Pt, Ni, Cu, W, Ta, Fe, Cr, Mg, Ga, Rh, Ti, Ru, Pd, In, Bi, Yb, or Ca, alloys or mixtures of these materials, and stacks of these materials. In some embodiments, the enhancement layer is a stack of a first layer and a second layer. In some embodiments, the first layer comprises a first material and the second layer comprises a second material. In some embodiments, the first layer acts to promote better growth of the second layer. In some embodiments, the first layer may comprise, but not limited to, Al, Yb, Ca, Ge, In, Bi, Mg, Cr, Sr, Ba, and Ti or alloys or mixtures of these materials. In some embodiments the second layer may comprise, but not limited to, Ag, Al, Au, Ir, Pt, Ni, Cu, W, Ta, Fe, Cr, Mg, Ga, Rh, Ti, Ru, Pd, In, Bi, or alloys or mixtures of these materials. In some embodiments, the stack of the enhancement layer may also comprise a third layer. In some embodiments, the third layer comprises a third material. In some embodiments, the first material and the third material may be different. In some embodiments the first material and the third material may be the same. In some embodiments, the third layer may comprise, but not limited to, Al, Yb, Ca, Ge, In, Bi, Mg, Cr, Sr, Ba, and Ti or alloys or mixtures of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials described herein provide methods for controlling the propagation of light that can enhance the device performance in a number of ways.

In some embodiments, the organic layer can generate one or more excited states in response to an excitation mechanism. In some embodiments, the excitation mechanism can include but not limited to an electrical pumping mechanism, a chemical reaction, and an optical pumping mechanism. A voltage applied to the device can electrically create the excited states. Optical pumping may include absorption of photons, including qabsorption of laser light, electron beam excitation, x-ray and/or microwave excitation, which may require additional up-conversion to achieve visible wavelengths. The excited states may be pumped via plasmon modes or other quasiparticles, as well as radiation-less energy transfer mechanisms like Forster resonance energy transfer (FRET) and single- or multiple-electron transfer either directly from the plasmonic material or another excited state, including Dexter electron transfer (DET).

In some embodiments, the excited-state energy can be directly transferred to the plasmon polariton mode through near-field coupling of the excited-state energy; or through single- or multiple-electron transfer either directly to the plasmonic material or another excited state that subsequently transfers energy into the plasmon mode. In some embodiments, the excited-state energy can be indirectly transferred to the plasmon polariton mode through an energy cascade, including FRET and DET, that transfers excited-state energy to another excited state that subsequently couples energy into the plasmon mode; through photon emission that subsequently interacts with the plasmonic material to achieve the momentum matching conditions required to excite a plasmon polariton; through photon emission that subsequently interacts with a grating or surface roughness resulting in a change in momentum of the photon leading to the new momentum matching conditions required to excite a plasmon polariton; through photon emission and subsequent reabsorption, possibly by another material in another layer or by the emitter material itself (self-absorption), with the resulting excited-state energy coupling to the plasmon mode.

In some embodiments, the percentage of energy transfer from the one or more excited states generated in the organic layer to the plasmon polariton mode supported by the plasmonic material is selected from the group consisting of: at least 5%, at least 10%, at least 20%, at least 30%, at least 40%, at least 50%, at least 60%, at least 70%, at least 80%, and at least 90%. This percentage is also referred to as incoupling fraction.

In order to calculate incoupling fraction, two device samples are made on a substrate with a transparent conducting oxide as the first electrode (anode): Sample 1, a plasmon device with thin ETL (e.g., 100 Å) and 1000 Å Ag cathode; Sample 2, a reference device with a thick ETL (e.g., 600 Å) and 1000 Å Al cathode. Both devices have a thin EML (e.g., 100 Å) with the same components. All other layers remain the same material and same thickness between the devices. Each of the devices has EQE and EL transient measured. It is assumed the plasmon coupling/transfer in the reference device is negligible due to both distance from the EML to the cathode and the Al cathode, though some real but small amounts of plasmon coupling likely exist. This assumption means that the rate constant of plasmon coupling is 0 and a system of equations can be established to solve for the total radiative and non-radiative decay rate constants of the emitter within that host system and thin EML.

$$\frac{{EQE}_{Ref .}}{g} = \frac{{k}_{R}}{( {k}_{R} + {k}_{NR} )} \qquad ( 1 )$$

$$\frac{1}{{τ}_{Ref .}} = {k}_{R} + {k}_{NR} \qquad ( 2 )$$

In equations 1 and 2, where EQE_{Ref.} is the measured EQE value of the reference device (Sample 2), τ_{Ref.} is the time constant fit to the EL transient data of the reference device (in seconds), g is the geometric factor of the device, k_{R} is the radiative rate constant, and k_{NR} is the non-radiative rate constant. For the reference device, the value for g is assumed to be 0-0.4 and must always exceed the measured EQE of the reference device. The geometric factor can be modeled for a given emitter dipole orientation. Since EQE_{Ref} is known, g is known, and τ_{Ref} is known, we can solve the two equations for k_{R} and k_{NR}.

Solving the two equations above gives k_{R} and k_{NR}. These are the decay rate constants of the emissive material within the thin EML. Because the same EML is present in the plasmonic and the reference device we assume that k_{NR} from the reference device is the same in plasmon device. Then for the plasmon device, we can write an expression for the EQE and transient of a plasmonic device where the plasmon incoupling rate constant (kₚ) is non-zero.

$$\frac{{EQE}_{p l a s mon .}}{g} = \frac{{k}_{{R}_{p l asmon}}}{( {k}_{{R}_{p l asmon}} + {k}_{NR} + {k}_{P} )} \qquad ( 3 )$$

$$\frac{1}{{τ}_{p l a s m o n}} = {k}_{{R}_{p l a s m o n}} + {k}_{N R} + {k}_{P} \qquad ( 4 )$$

In equations 3 and 4, where EQEₚₗₐₛₘₒₙ is the measured EQE value of the plasmon device (Sample 1), τₚₗₐₛₘₒₙ is the time constant fit to the EL transient of the plasmon device (in seconds), g is the geometric factor of the device, k_{Rplasmon} is the radiative rate constant of the plasmon device, k_{NR} is the non-radiative rate constant (assumed to be the same as the reference device), and kₚ is the plasmon incoupling rate constant. The value for g is assumed to be the same as the reference device. The two equations above can be used to solve for kₚ and k_{Rplasmon}. Once all rate constants have been found for the plasmon device, the plasmon incoupling fraction (or yield of excitations that are coupled/transferred to the plasmon mode) can be calculated using the following equation 5:

$$Incoupling fraction = \frac{{k}_{P}}{{k}_{{R}_{p l asmon}} + {k}_{N R} + {k}_{P}} \qquad ( 5 )$$

In some embodiments, the enhancement layer comprises the plasmonic material exhibiting plasmon resonance that may non-radiatively couple to the excited state forming material in the organic layer, such as the emitter material, and transfer excited-state energy from the excited state forming material to the plasmon polariton modes of the enhancement layer. In some embodiments, the excited state forming material in the organic layer is provided no more than a threshold distance away from the enhancement layer, wherein the threshold distance is a distance at which

$$\frac{{k}_{{R}_{p l asmon}}}{{k}_{P}} = \frac{{k}_{R}}{{k}_{N R}} .$$

In another word, if the inequality below holds:

$$\frac{{k}_{{R}_{p l asmon}}}{{k}_{P}} < \frac{{k}_{R}}{{k}_{N R}} ,$$

then the organic layer is within a threshold distance. The enhancement layer modifies the effective properties of the medium in which the excited state forming material resides resulting in any or all of the following: a decreased excited state lifetime of emission, a modification of emission line-shape, a change in emission intensity with angle, a change in the stability of the excited state forming material, a change in the efficiency of the device, new hybridized modes in the device including plexitons or plasmon polaritons, and a reduced efficiency roll-off of the device. Placement of the enhancement layer on the cathode side, anode side, or on both sides, or the enhancement layer itself being as the CGL, results in devices which take advantage of any of the above-mentioned effects.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength sized features and the sub-wavelength sized features have sharp edges. Within the enhancement layer, the wavelength sized or sub-wavelength sized features may be all partially etched through, all fully etched through, or both partially and fully etched through the thickness of the plasmonic material. In some embodiments, the wavelength sized or sub-wavelength sized features may be formed from a plurality of nanoparticles. In some embodiments, the enhancement layer may comprise void in areas around and/or between the wavelength sized or sub-wavelength sized features. Here, the void may be “air”, an inert gas, or a void formed by dielectric material, the same or different metal material than the wavelength sized or sub-wavelength sized, organic or inorganic emissive material, etc.

In some embodiments, the device further comprises an outcoupling layer. In some embodiments, the outcoupling layer is disposed over the enhancement layer on a side opposite the organic layer. In some embodiments, the outcoupling layer can also be disposed between the organic layer and the enhancement layer but still outcouples energy from the plasmon mode of the enhancement layer. The outcoupling layer scatters or extracts energy from the plasmon polaritons. In some embodiments this energy is scattered or extracted as photons to free space. In some embodiments, the percentage of the energy transferred to the plasmon polariton mode being converted into photons in free space, also called as outcoupling fraction, is selected from the group consisting of: at least 5%, at least 10%, at least 20%, at least 30%, at least 40%, at least 50%, at least 60%, at least 70%, at least 80%, and at least 90%. The external quantum efficiency of the plasmonic device can be defined as the product of the plasmon incoupling fraction and the plasmon outcoupling fraction (EQEₚₗₐₛₘₒₙ=incoupling fraction*outcoupling fraction). Factors governing the internal quantum efficiency (IQE) are still valid, including charge recombination efficiency, excited state forming material photoluminescence quantum yield, etc. and the total EQE of the device will be affected by the IQE. In some other embodiments, the energy is extracted from the plasmon mode into other modes of the device such as but not limited to the organic waveguide mode, the substrate mode, or another waveguiding mode. If energy is scattered or extracted to the non-free space mode of the device, additional outcoupling schemes may be incorporated to eventually extract the energy to free space.

In order to calculate the outcoupling fraction, a third device sample will need to be made. Sample 3, a plasmon device with thin ETL (e.g., 100 Å), thin Ag cathode (e.g., 300 Å), and outcoupling layer. All other layers in Sample 3 are kept the same as those in Samples 1 and 2. The EQE is measured on Sample 3, where the EQE from the side of the device that the outcoupling layer is designed to extract energy from is EQE_{OL}. Together with the incoupling fraction obtained above, the outcoupling fraction can be obtained through the following equation 6.

$$Outcoupling fraction = \frac{{EQE}_{O L}}{Incoupling fraction} \qquad ( 6 )$$

In some embodiments, the outcoupling layer has wavelength-sized or sub-wavelength sized features that are arranged periodically, quasi-periodically, or randomly. In some embodiments, the outcoupling layer may be composed of a plurality of nanoparticles. In some embodiments, the outcoupling layer is composed of a plurality of nanoparticles disposed over a material. In these embodiments the outcoupling layer may be tunable by at least one of: varying a size of the plurality of nanoparticles, varying a shape of the plurality of nanoparticles, changing a material of the plurality of nanoparticles, adjusting a thickness of the material, changing the refractive index of the material, adding an additional layer disposed on the plurality of nanoparticles, varying a thickness of the enhancement layer, or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material that is coated with a shell of a different material with the same type or different type. In some embodiments, the outcoupling layer is composed of at least metal nanoparticles wherein the metal is, but not limited to, Ag, Al, Au, Ir, Pt, Ni, Cu, W, Ta, Fe, Cr, Mg, Ga, Rh, Ti, Ru, Pd, In, Bi, Yb, and Ca, alloys or mixtures of these materials, and stacks of these materials. In some embodiments, the outcoupling layer is composed of dielectric materials such as, but not limited to, indium tin oxide, tin oxide, tin dioxide, silicon nitride, boron nitride, silicon carbide, carbon, diamond, zinc sulfide, zinc selenide, germanium, zinc telluride, potassium niobate, titanium oxide, aluminum oxide, titanium dioxide, antimony oxide, indium dioxide, silicon dioxide, niobium pentoxide, tantalum pentoxide, vanadium oxide, vanadium pentoxide, gallium phosphate, bismuth oxide, gallium arsenide, and/or aluminum gallium compounds, mixtures of these materials, and stacks of these materials. In some embodiments, the nanoparticles have a shape including but not limited to rectangle, cube, cylinder, rectangular pyramid, triangular pyramid, octahedra, hemispheres, cones, truncated cones, a random shape having a flat face, or may have random shapes. In some embodiments, the nanoparticles may have a maximum cross-sectional size within the shape between 5 nm and 1000 nm. In some embodiments, the nanoparticles may have an in-plane dimension (largest dimension measured parallel to the organic layer) between 5 nm and 500 nm. In some embodiments, nanoparticles may have an out-of-plane dimension (largest dimension measured perpendicular to the organic layer) between 5 nm and 500 nm. In some embodiments, the outcoupling layer may have wavelength sized or sub-wavelength sized features that are etched partially or fully through the thickness of the film. Within the outcoupling layer, the wavelength sized or sub-wavelength sized features may be all partially etched through, all fully etched through, or both partially and fully etched through the thickness of the film. In some embodiment, the wavelength sized or sub-wavelength sized features may be arranged periodically, quasi-periodically, or randomly.

In some embodiments, the outcoupling layer may comprise void in areas around and/or between the wavelength sized or sub-wavelength sized features. Here, the void may be “air”, an inert gas, or a void formed by dielectric material, the same or different metal material than the wavelength sized or sub-wavelength sized, organic or inorganic emissive material, etc. In some embodiments, the nanoparticles may have a refractive index selected from the group consisting of: at least 1.5, at least 2.0, at least 2.5, at least 3.0, and greater than 3.0. In some embodiments, the polarization of the emission can be tuned using the outcoupling layer. Varying the dimensionality and periodicity of the wavelength sized or sub-wavelength sized features in the outcoupling layer can select a type of polarization that is preferentially outcoupled to air. In some embodiments, the outcoupling layer can also act as an electrode, e.g., the first or second electrodes described herein. In some embodiments the outcoupling layer is formed by lithography.

In some embodiments, optically active metamaterials and hyperbolic materials maybe be utilized in the outcoupling layer. In some embodiments, metamaterials or hyperbolic materials with anisotropic optical constants may be used in the outcoupling layer to control emission phase and polarization state of the emission. Metamaterials with high permittivity above 5 may be used in the outcoupling layer to enhance light outcoupling efficiency, narrow the emission line shape and emission wavefront shaping.

In some embodiments, the outcoupling layer may further comprise one or more spacer layers between the enhancement layer and the wavelength sized or sub-wavelength sized features. In some embodiments, the spacer layer may comprise one or more dielectric material and may be referred to as a dielectric layer and/or an intervening layer. In some embodiments, the spacer layer may have a refractive index selected based on a color of light emitted by the excited state forming material. In some embodiments, the spacer layer may be found only in a plasmonic sub-pixel, only in a non-plasmonic sub-pixel or in both. Examples of material suitable for use in the spacer layer include but not limited to dielectric materials, including organic, inorganic, perovskites, oxides, organic materials, semiconductor materials, fluorides, metal organic frameworks (MOFs), covalent organic frameworks (COFs), quantum dots, and may include stacks and/or mixtures of these materials. In some embodiments, the spacer layer may comprise void in areas around and/or between the wavelength sized or sub-wavelength sized features. Here, the void may be “air”, an inert gas, or a void formed by dielectric material, the same or different metal material than the wavelength sized or sub-wavelength sized, organic or inorganic emissive material, etc.

In some embodiments, the outcoupling layer may further comprise one or more over layers disposed over the wavelength sized or sub-wavelength sized features on a side opposite the enhancement layer. In some embodiments, the over layer may include dielectric materials, including organic, inorganic, perovskites, oxides, organic materials, semiconductor materials, fluorides, metal organic frameworks (MOFs), covalent organic frameworks (COFs), quantum dots and may include stacks and/or mixtures of these materials. In some embodiments, the over layer may also act as a barrier to water or oxygen permeation of the device. In some embodiments, the over layer may be a color altering layer or color filtering layer. In some embodiments, the over layer can have a thickness selected from the group consisting of: less than 500 nm, less than 250 nm, less than 100 nm, less than 50 nm, less than 40, less than 30, less than 20, and less than 10 nm. In some embodiments, the over layer may comprise void in areas around and/or between the wavelength sized or sub-wavelength sized features. Here, the void may be “air”, an inert gas, or a void formed by dielectric material, the same or different metal material than the wavelength sized or sub-wavelength sized, organic or inorganic emissive material, etc.

In some embodiments, any of the wavelength sized or sub-wavelength sized features described herein in different layers may have a closest edge to edge spacing between each adjacent feature selected from the group consisting of: less than 10 nm, less than 25 nm, less than 50 nm, less than 200 nm, or less than 1 micron. In some embodiments, the wavelength sized or sub-wavelength sized features may have a center-to-center spacing selected from the group consisting of: less than 100 nm, less than 300 nm, or less than 500 nm. In some embodiments, the wavelength sized or sub-wavelength sized features may form arrays having periodic positional ordering exhibiting hexagonal, square, rectangular, oblique, rhombic, honeycomb, or any other type of lattice symmetry. In some embodiments, the arrays may have a lattice periodicity selected from the group consisting of: at least 100 nm, at least 200 nm, at least 300 nm, at least 400 nm, and more than 500 nm. In some embodiments, the wavelength sized or sub-wavelength sized features may form two or more arrays. Here, each array of the two or more arrays may have the same lattice symmetry or may have different lattice symmetry, or any combination thereof. Additionally, each array of the two or more arrays may have the same lattice periodicity, different lattice periodicity, or any combination thereof. In some embodiments, each array of the two or more arrays may be rotated relative to the other arrays of the two or more arrays. In some embodiments, the wavelength sized or sub-wavelength sized features may form a Penrose design or a Moiré array.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant, as disclosed in U.S. Pat. No. 9,960,386 and incorporated by reference in its entirety. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered or extracted as photons to free space. In other embodiments, the energy is scattered or extracted from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric spacer layers can be disposed between the enhancement layer and the outcoupling layer. The plasmonic stack may include a dielectric spacer material (i.e., a spacer layer) having a refractive index selected based on a color of light emitted by the organic emissive material. In an embodiment, the dielectric spacer material (i.e., spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of either electrode, outside of the plasmonic stack. In yet another embodiment, the dielectric spacer material may be located between the enhancement layer and the outcoupling layer or may be integrated within the outcoupling layer. In some embodiments, the dielectric spacer layer may be found only in a plasmonic stack sub-pixel, only in a non-plasmonic stack sub-pixel or in both. Examples of material suitable for use in dielectric spacer layers include dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, an optical communication device, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C. Additionally, devices fabricated in accordance with embodiments of the invention may be incorporated into optical communication devices.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Organic light emitting devices (OLEDs) that leverage coupling of electrically-excited excitons into a plasmon polariton mode of a nearby enhancement layer may benefit from improved device stability. Energy from the plasmon polariton mode may be efficiently converted to light to create bright devices. However, in some instances, the excited state energy may be coupled into the plasmon polariton mode with less than unity efficiency, leading to residual photon generation from the excited state energy that is not coupled into the plasmon polariton mode that may not be harvested. Embodiments of the disclosed subject matter provide device structures that may harvest this photon energy and couple it into the plasmon mode as a photon-induced plasmons (PIP). Further, that coupled energy may be utilized to produce photons similar to excited state energy that is coupled directly into the plasmon mode and out-coupled as light. In an embodiment, due to the reflector layer described below, light output from the same side of the device may include, for example, plasmon out-coupled light (i.e., light emitted outside the electrodes by an outcoupling layer) and additional transmitted residual light (i.e., light emitted inside the electrodes from the organic layer) that does not transfer its energy to the plasmon polariton to form a PIP. For practical purposes such as in display applications and the like, a device that emits light out of a single side may be useful, as the electronics driving the display may be on the non-emissive side (i.e., where light may not be transmitted through).

Electrically excited state energy in the form of excitons may transfer energy through near-field coupling into the plasmon polariton mode of a nearby enhancement layer, such as a metal cathode and/or anode, or some other plasmonically-active material or metamaterial, as described above. As the emissive layer (EML) is placed closer to the enhancement layer, the plasmon coupling may increase, and the residual non-plasmon-coupled light emission may decrease. Embodiments of the disclosed subject matter may provide devices that operate on the principle that charges injected into the device may form excitons. The excitons may radiatively decay to emit photons within the device stack. The emitted photons may couple into the surface plasmon mode of the enhancement layer, where they may be subsequently reconverted to photons by the outcoupling layer. In some embodiment, at least 5% of the light emitted from the device by using the aforementioned process. In some embodiment, at least 10% of the light emitted from the device by using the aforementioned process. Due to practical considerations of device stability, charge balance, yield, and the like, it may be unlikely that the EML may be placed close enough to the enhancement layer to achieve unity plasmon incoupling efficiency (i.e., the incoupling fraction being 100%).

Embodiments of the disclosed subject matter may provide device structures where the photons emitted within the device may be harvested through the plasmon polariton mode as a PIP and out-coupled as light. Any remaining light present in the device cavity that does not couple into the plasmon mode may be reflected and transmitted through the enhancement layer, absorbed in some other layer, and/or waveguided and lost within the device stack. These alternatives may typically have lower outcoupling efficiency than some embodiments in which the light couples into the plasmon mode and may be reconverted to light. The photons present in the device cavity may have originated within the device cavity, for example, via electrical or photoexcitation of an emissive species, for an example an emissive material, or may have been coupled into the device cavity from outside the device (e.g. ambient light).

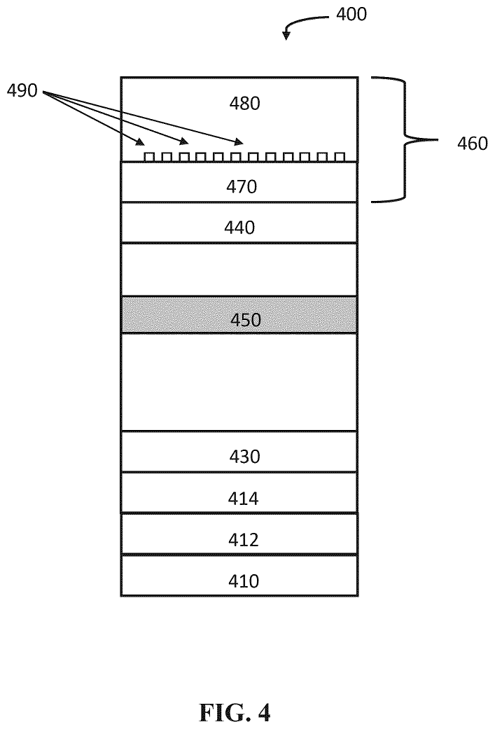

As shown in FIG. 4, in an embodiment, the layers of device 400 are disposed on substrate 410 and include a reflector layer 412 which may be, but is not required to be, disposed adjacent to the first electrode 430 on a side of the organic layer 450 opposite the second electrode 440. Here, the second electrode 440 functions as an enhancement layer. In an embodiment, the reflector layer 412 may be an opaque metal layer or a dielectric layer. In some embodiments, a diffuser layer 414 may be disposed between the first electrode 430 and the reflector layer 412. It should be noted the diffuser layer 414 is optional and may only be found in some embodiments. In some embodiments, the reflector layer 412 may serve as an electrode for the device, in other words the reflector layer 412 may be the first electrode 430 and the two layers (e.g. 412 and 430) may be a single layer. In this embodiment, while not shown in FIG. 4, the optional diffuser layer 414 may be disposed between the combined reflector layer 412/first electrode 430 and the second electrode 440. Since the enhancement layer may be a metal, typically one that is semitransparent, the reflector layer 412 shown in FIG. 4 may be used with the second electrode 440 to establish a microcavity for the device. In an embodiment, the microcavity may be formed when the reflector layer 412 is not combined with the first electrode 430 and the first electrode 430 is transparent. Alternatively, the microcavity may be formed when the reflector layer 412 is combined with the first electrode 430 to form a single layer, and this combined layer may form a microcavity with the second electrode 440. The microcavity may be used to tune one or more decay rate constants in the device, such as a radiative decay rate, non-radiative decay rate, and/or plasmon coupling rate, either in varying ratios or efficiencies with which the energy transfer processes occur. In an embodiment, as described above, device 400 may include a diffuser layer 414 but is not required, and the diffuser layer 414 may spread, homogenize, and/or shape the light that passes through the diffuser layer 414. In an embodiment, device 400 may also include an outcoupling layer 460 which may include spacer layer 470, nanoparticles 490, and/or an overlayer 480.

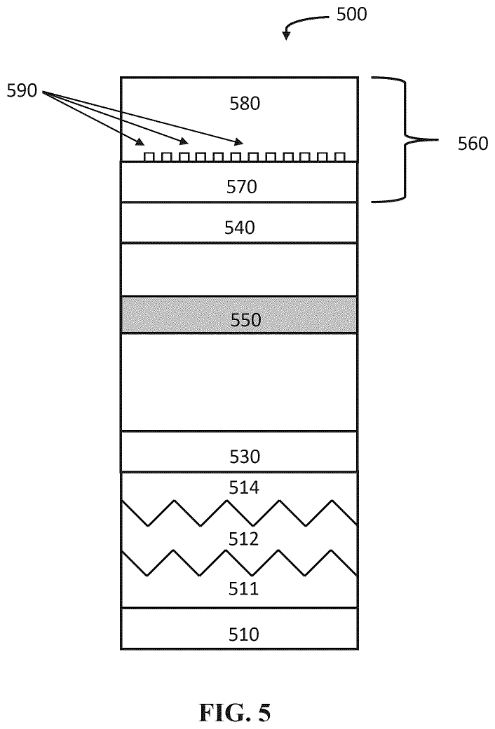

As shown in FIG. 5, in an embodiment, the layers of device 500 are disposed on substrate 510 and include a reflector layer 512 which may be, but is not required to be, disposed adjacent to the first electrode 530 on a side of the organic layer 550 opposite the second electrode 540. Here, the second electrode 540 functions as an enhancement layer. In an embodiment, the reflector layer 512 may be an opaque metal layer or a dielectric layer. In some embodiments, a diffuser layer 514 may be disposed between the first electrode 530 and the reflector layer 512. It should be noted that the diffuser layer 514 is optional and may only be found in some embodiments. In some embodiments, device 500 may also include a corrugated layer 511. In some embodiments, the corrugated layer 511 may include the corrugated structures, as described below. In an embodiment, when a corrugated layer 511 is included in device 500, a layer between the corrugated layer 511 and the first electrode 530 may be planarized. In an embodiment, as shown in FIG. 5, the diffuser layer 514 may be planarized and the first electrode 530 is disposed on the planarized diffuser layer 514. In an embodiment, the diffuser layer 514 may not be included in the device 500, and the reflector layer 412 may be planarized. In some embodiments, the reflector layer 512 may serve as an electrode for the device, in other words the reflector layer 512 may be the first electrode 530 and the two layers (e.g., 512 and 530) may be a single layer. In this embodiment, while not shown in FIG. 5, the optional diffuser layer 514 may be disposed between the combined reflector layer 512/first electrode 530 and the second electrode 540. Similar to the discussion of FIG. 4, since the enhancement layer may be a metal, typically one that is semitransparent, the reflector layer 512 shown in FIG. 5 or the combined reflector layer 512/first electrode 530 may be used with the second electrode 440 to establish a microcavity for the device. In an embodiment, as described above, device 500 may include a diffuser layer 514 but is not required, and the diffuser layer 514 may spread, homogenize, and/or shape the light that passes through the diffuser layer 514. In an embodiment, device 500 may also include an outcoupling layer 560 which may include spacer layer 570, nanoparticles 590, and/or an overlayer 580.

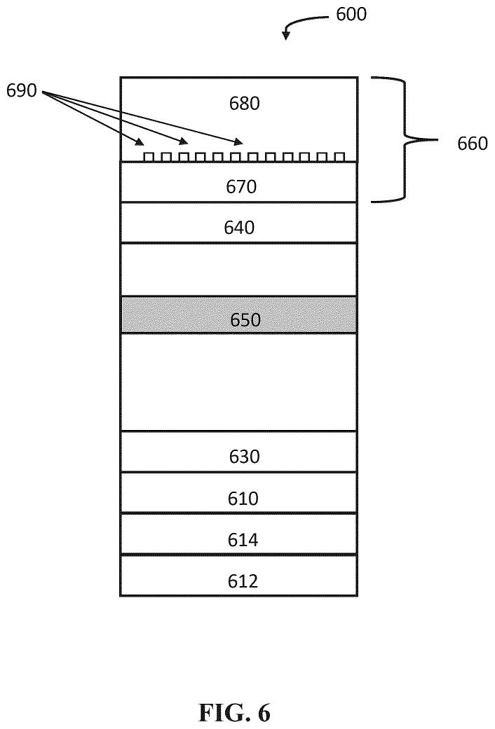

As shown in FIG. 6, in an embodiment, device 600 includes an outcoupling layer 660, first electrode 630, second electrode 640 and an organic layer 650 disposed over substrate 610. In an embodiment, a reflector layer 612 and diffuser layer 614 may be disposed under the substrate 610, on a side opposite the outcoupling layer 660, first electrode 630, second electrode 640 and an organic layer 650. Here, the second electrode 640 functions as an enhancement layer. In an embodiment, the reflector layer 612 may be an opaque metal layer or a dielectric layer. In some embodiments, a diffuser layer 614 may be disposed between the substrate 610 and the reflector layer 612. It should be noted that the diffuser layer 614 is optional and may only be found in some embodiments. In an embodiment, the diffuser layer 614 may spread, homogenize, and/or shape the light that passes through the diffuser layer 614. In an embodiment, the outcoupling layer 660 may include spacer layer 670, nanoparticles 690, and/or an overlayer 680.

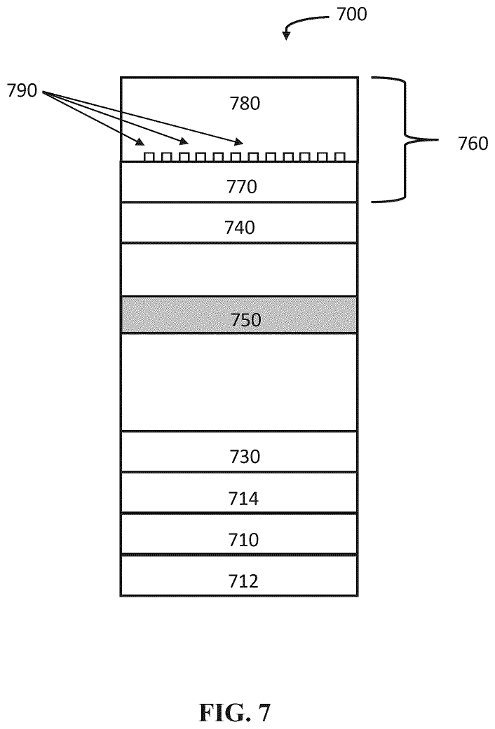

As shown in FIG. 7, in an embodiment, device 700 includes an outcoupling layer 760, first electrode 730, second electrode 740 and an organic layer 750 disposed over substrate 710. In an embodiment, a reflector layer 712 may be disposed under the substrate 710, on a side opposite the outcoupling layer 760, first electrode 730, second electrode 740 and an organic layer 750. Here, the second electrode 740 functions as an enhancement layer. In an embodiment, the reflector layer 712 may be an opaque metal layer or a dielectric layer. In some embodiments, a diffuser layer 714 may be disposed between the substrate 610 and the first electrode 730. It should be noted that the diffuser layer 714 is optional and may only be found in some embodiments. In an embodiment, the diffuser layer 714 may spread, homogenize, and/or shape the light that passes through the diffuser layer 714. In an embodiment, the outcoupling layer 760 may include spacer layer 770, nanoparticles 790, and/or an overlayer 780.

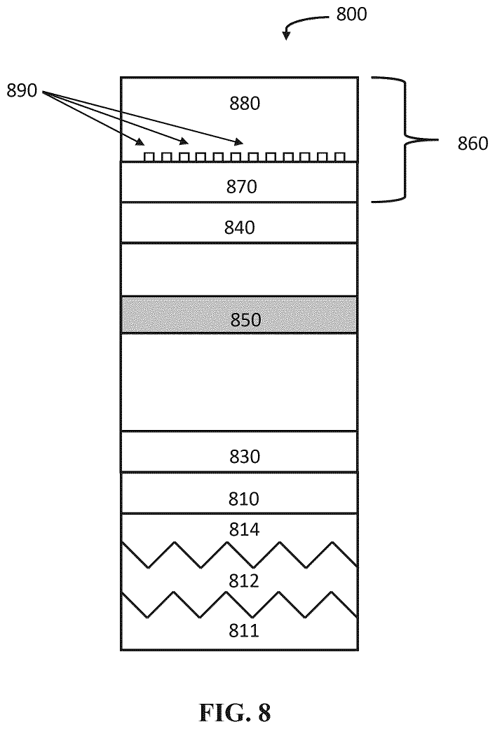

As shown in FIG. 8, in an embodiment, device 800 includes an outcoupling layer 860, first electrode 830, second electrode 840 and an organic layer 850 disposed over substrate 810. In an embodiment, a diffuser layer 814, reflector layer 812, and corrugated layer 811 may be disposed under the substrate 810, on a side opposite the outcoupling layer 860, first electrode 830, second electrode 840 and an organic layer 850. Here, the second electrode 840 functions as an enhancement layer. In an embodiment, the reflector layer 812 may be an opaque metal layer or a dielectric layer. In some embodiments, a diffuser layer 814 may be disposed between the substrate 810 and the reflector layer 812. It should be noted, the diffuser layer 814 is optional and may only be found in some embodiments. In some embodiments, the corrugated layer 811 may include the corrugated structures, as described below. In an embodiment, when a corrugated layer 811 is included in device 800, a layer between the corrugated layer 811 and the first electrode 830 may be planarized. In an embodiment, as shown in FIG. 8, the diffuser layer 814 may be planarized and the first electrode 810 is disposed on the planarized diffuser layer 814. In an embodiment, the diffuser layer 814 may not be included in the device 800, and the reflector layer 812 may be planarized. In an embodiment, the diffuser layer 814 may spread, homogenize, and/or shape the light that passes through the diffuser layer 814. In an embodiment, the outcoupling layer 860 which may include spacer layer 870, nanoparticles 890, and/or an overlayer 880.

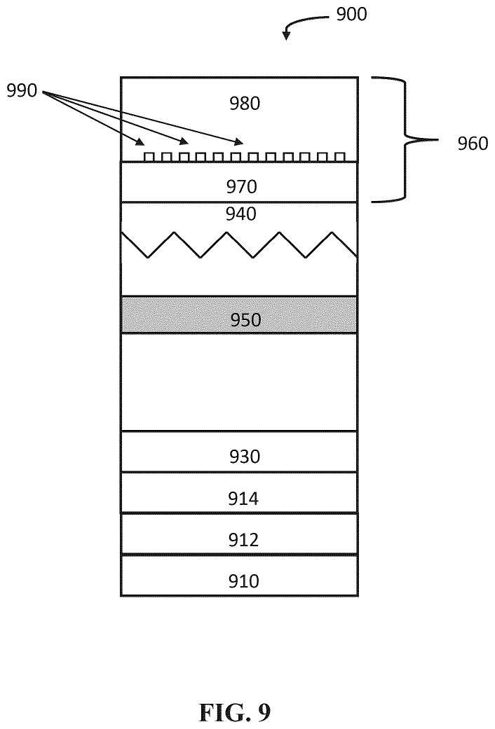

As shown in FIG. 9, in an embodiment, the layers of device 900 are disposed on substrate 910 and include a reflector layer 912 which may be, but is not required to be, disposed adjacent to the first electrode 930 on a side of the organic layer 950 opposite the second electrode 940. Here, the second electrode 940 functions as an enhancement layer and the second electrode is corrugated. In an embodiment, the reflector layer 912 may be an opaque metal layer or a dielectric layer. In some embodiments, a diffuser layer 914 may be disposed between the first electrode 930 and the reflector layer 912. It should be noted that the diffuser layer 914 is optional and may only be found in some embodiments. In some embodiments, the reflector layer 912 may serve as an electrode for the device, in other words the reflector layer 912 may be the first electrode 930 and the two layers (e.g., 912 and 930) may be a single layer. In this embodiment, while not shown in FIG. 9, the optional diffuser layer 914 may be disposed between the combined reflector layer 912/first electrode 930 and the second electrode 940. Since the enhancement layer may be a metal, typically one that is semitransparent, the reflector layer 912 shown in FIG. 4 may be used with the second electrode 940 to establish a microcavity for the device. In an embodiment, the microcavity may be formed when the reflector layer 912 is not combined with the first electrode 930 and the first electrode 930 is transparent. Alternatively, the microcavity may be formed when the reflector layer 912 is combined with the first electrode 930 to form a single layer, and this combined layer may form a microcavity with the second electrode 940. The microcavity may be used to tune one or more decay rate constants in the device, such as a radiative decay rate, non-radiative decay rate, and/or plasmon coupling rate, either in varying ratios or efficiencies with which the energy transfer processes occur. In an embodiment, as described above, device 900 may include a diffuser layer 914 but is not required, and the diffuser layer 914 may spread, homogenize, and/or shape the light that passes through the diffuser layer 914. In an embodiment, device 900 may also include an outcoupling layer 960 which may include spacer layer 970, nanoparticles 990, and/or an overlayer 980.

In any of the devices described above, the reflector layer (e.g., 412, 512, 612, etc.) may be a distributed Bragg reflector (DBR). DBRs may be configured to reflect light over a certain wavelength range. This may be used to tune the color of the reflected light. For example, a broad emitter that is configured to emit light from 550-650 nm may interact with a DBR that is tuned to reflect light from 500-600 nm. This may narrow the emission spectrum of the reflected light to 550-600 nm, thereby adjusting the color point of not only the reflected light, but also the color point of the overall device, which may include plasmon-outcoupled light.

Surface plasmons may be generated by coupling to light from the far field, usually with a grating, hemisphere, or the like, as discussed above and below in relation to the corrugated layer (e.g., 511, 811, and 940). Embodiments of the disclosed subject matter may provide devices that utilize the photons present within the device cavity to generate PIPs, as shown in FIGS. 4-9. In one embodiment, a diffuser layer may be placed in front of the reflector (e.g., either dielectric or metal) layer to scatter light at high angles such that surface plasmons may be generated when that high-angle light is incident on the surface of the enhancement layer such as shown in FIGS. 4-9.

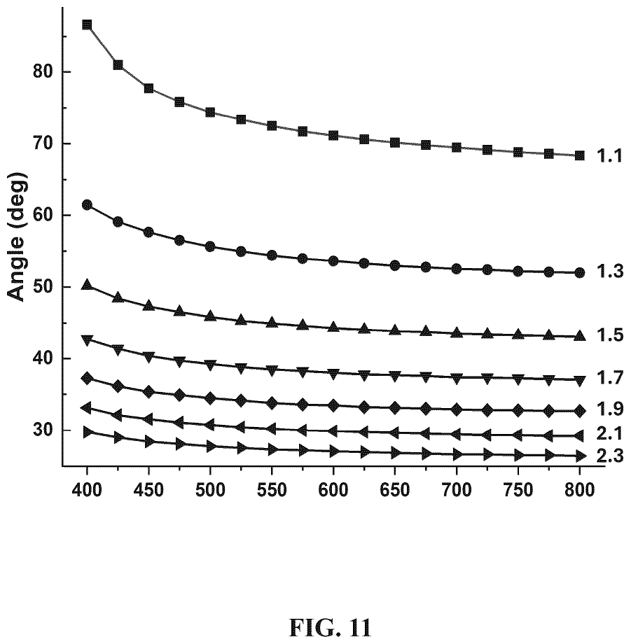

FIG. 11 shows a plot of the optimal angle of incidence versus wavelength to generate a surface plasmon polariton in Ag layer for light incident between a dielectric Ag interface, estimated for different index of refraction of the dielectric medium (i.e., index of the refraction of the dielectric medium is the overall refractive index of the one or more layers between the reflector layer and the enhancement layer) according to embodiments of the disclosed subject matter. When the material (i.e. Ag layer) between the two reflective electrodes is composed of multiple materials, typically n is calculated using the effective index approximation. A simplified description of the effective index approximation is that it is an average of the refractive index of each material weighted by its thickness. This approximation is best applied when the layers in the device have a thickness less than the wavelength of light as is often the case in OLED devices. The optimal angle incidence was estimated using a transfer matrix-based calculation, assuming 30 nm Ag layer with a dielectric medium on bottom surface and air on the top surface of the Ag layer. It should be noted that and is recognized by the inventors, as the thickness of the Ag layer changes, there is a change in the cross-coupled plasmon modes, and the plot of the optimal angle of incidence versus wavelength to generate a surface plasmon may change. The angle of incidence may be defined as the angle between an incident beam and normal to the Ag layer, with 0 degrees being perpendicular to the enhancement layer. The appropriate condition may be dependent on the wavelength of light. The surface plasmons may be subsequently outcoupled as light via the outcoupling layer. Any of the diffuser layers (e.g., 414, 514, 614, etc.) described above may be a thin film of scattering dielectric nanoparticles or air bubbles embedded in a transparent polymer matrix, or the like. In one embodiment, the interface between the diffuser layer and an adjacent layer may be smooth, and the effective refractive index may be similar to the adjacent layer, for example a glass substrate, in order to minimize losses at the interface.

As shown in FIGS. 4-9, the diffuser layer (e.g., 414, 514, 516, etc.) may be on the same side of the substrate as the reflector layer, where both the diffuser layer and the reflector layer are on a side of the substrate opposite the organic layer of the device as shown in FIG. 6, or the diffuser layer is on the same side of the substrate as the organic layer with the reflector layer on the opposite side of the substrate as the organic layer as shown in FIG. 7, or both the reflector layer and diffuser layer can be on the same side of the substrate, as shown in FIG. 4. Light generated inside the device may interact with the diffuser layer before it interacts with the reflector layer, but the diffuser layer may be located at any location between the reflector layer and the enhancement layer. In another embodiment, the reflector layer itself may be diffusive. As described above, the diffuser layer is optional, and the reflector layer may be provided within any device without the inclusion of the diffuser layer.

To achieve the appropriate in-plane momentum matching conditions to excite a surface plasmon, the light may reach the enhancement layer at non-normal incidence. In general, the plasmon excitation angle at any metal-dielectric interface may depend on the refractive index of the dielectric medium and wavelength of the light. FIG. 11 shows the optimal angle of incidence versus wavelength plot for the light incident at the interface between a dielectric medium and a planar Ag layer of thickness 30 nm estimated for different effective refractive index of the dielectric medium. The angle of incidence is defined as the angle between incident beam and normal to the AG layer, with 0 degrees being perpendicular to the enhancement layer. In general, the plasmon excitation angle at any metal-dielectric interface may depend on the refractive index of the dielectric medium. At any specific wavelength of light, the optimal angle of incidence may increase with the decrease in refractive index of the dielectric medium. In an example device, for an OLED device, using 30 nm thick Ag enhancement layer the optimal angle of incidence for the visible light within wavelength range 450-650 nm incident at the organic-enhancement layer to generate PIP may be 45±10°. The enhancement layer may be designed to be non-planar, which may include corrugation or other array features etched into, protruding from, or otherwise incorporated into the shape of the enhancement layer, as shown in FIG. 9. In these cases, an incident photon will couple into the surface plasmon mode when it meets the enhancement layer array resonance condition for both wavelength and angle.

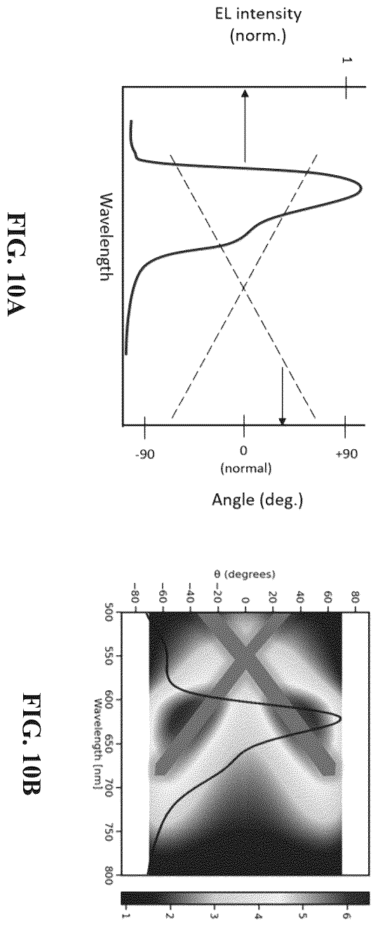

FIGS. 10A and 10B show the concept of offsetting the resonance of a reflector layer grating with the intrinsic emitter spectrum such that photons are reflected at oblique angles suitable for generating surface plasmons. FIG. 10A shows this concept schematically, and FIG. 10B shows this concept using angle resolved electroluminescent data from an OLED. For example, referring to the dispersive mode shown in FIGS. 10A-10B, any angle/wavelength combination that satisfies the array's dispersion relation may enable photon-to-plasmon coupling. In any of the embodiments described above, the diffuser layer may accomplish this by scattering light in all directions. Light that does not reach the enhancement layer at the plasmon incoupling angle may be reflected back toward the diffuser layer, where it may have another chance to scatter off at a higher angle, or otherwise may scatter at an angle suitable for plasmon coupling. In an example embodiment, Ag may be utilized for the enhancement layer, and Al may be used for the reflector layer so that the Al reflector layer does not parasitically absorb the desired PIPs and instead reflects them toward the Ag enhancement layer to produce PIPs that can be subsequently outcoupled by the outcoupling layer. When simulating the angle of incoupling for Al and Ag for an effective refractive index of ^{~}1.7, the angle of incoupling may be ^{~}36.5±5 degrees for Al and ^{~}42±5 degrees for Ag over the same wavelength range. In this way, using Al for the reflective layer with an Ag enhancement layer may increase the number of PIP events by reducing any possibility of exciting the surface plasmon resonance (SPR) modes in the reflective metal layer. In other embodiments, a dielectric bottom reflector layer and/or gratings (which may be metal or dielectric) may be used to avoid parasitic PIP absorption in the reflector layer. In some embodiments, the device stack may include a reflector layer that may be fully or partially corrugated (i.e., the corrugation propagates through the entire device stack thickness, or only through one or a few layers), Instead of, or in addition to, including a diffuser layer. The corrugation may be a one-dimensional (1D) or two-dimensions (2D) array, periodic, quasiperiodic, or aperiodic. The diffuser layer may be the corrugation layer, or may be a separate layer in addition to a corrugation layer, such as shown in FIGS. 5 and 8. As before, the corrugated reflector layer may be on between the first electrode and the substrate (such as shown in FIG. 5) or on the opposite side of the substrate from the first electrode (such as shown in FIG. 8).

In an example embodiment, the corrugated layer (e.g., 411, 811, etc.) or the corrugated enhancement layer 940, as shown in FIG. 9, may include a corrugated structure that may be a periodic array with a defined pitch. Periodic arrays, also known as gratings, may be dispersive elements that separate light into its different wavelength components. Arrays may diffract light off the periodic elements in the array with the constructive and destructive interference of light reflecting off, or transmitting though, these elements leading to light dispersion. Each incident wavelength may leave the array with a different angle, resulting in the x-shaped dispersive mode schematically depicted for an array as shown in FIGS. 10-10B. The array pitch may set the array resonance wavelengths. For example, finer array pitches may blue shift the resonance, and wider array pitches may red shift the resonance. The effective refractive index surrounding the array may affect the array resonance, with higher refractive index materials red shifting and lower refractive index materials blue shifting the array resonance. The pitch may be chosen such that reflection over the emission wavelengths occurs at higher angles, thereby increasing the likelihood of meeting the in-plane momentum matching condition to generate surface plasmons in the enhancement layer. For example, as shown in FIGS. 10A-10B, the array dispersion relation may cross the emission spectrum at roughly 45 degrees. This means that light of this wavelength may preferentially be reflected at 45 degrees, which may favor PIP coupling, such as shown in FIG. 11. If an angle greater (or less) than 45 degrees is desired, the array crossing wavelength at normal incidence may need to be separated further (brought closer) in wavelength space from the emission spectrum, which may be achieved, for example, by changing the pitch or the effective refractive index surrounding the array. In some embodiments, the array may be, but is not limited to, a component of the reflector layer or a component of the enhancement layer.

In an example embodiment, the corrugated structure may be a periodic array with a defined pitch, where the pitch can be chosen such that the array resonance at normal incidence for a particular lattice mode is mismatched (e.g., either red- or blue-shifted) with respect to the emitter's emission wavelength. This may cause reflection over the emission wavelength to occur at higher angles, thereby increasing the likelihood of meeting the in-plane momentum matching condition to generate surface plasmons in the enhancement layer, such as shown in FIGS. 10A-10B. For example, for a red device with an emission wavelength 620 nm using a square array of particles to reflect light, the array periodicity may be 265±5 nm or 580±5 nm. For green devices with an emission wavelength 520 nm, the array periodicity may be 220±5 nm or 500±5 nm. For blue devices with an emission wavelength 470 nm, a square array having a periodicity 200±5 nm or 450 nm±5 nm may be used.

The shape of the corrugation can be tuned to maximize the reflection at a preferred angle, such as a blazed grating. The reflector layer may be, but is not limited to: a photonic crystal, a metallic thin film, a dielectric material such as a DBR, and/or may be a combination thereof. In another embodiment, a device may incorporate an enhancement layer with a grating on the side facing the EML, which can also couple PIPs into the enhancement layer, such as shown in FIG. 9. The grating mode enables in-coupling of a broader k range, where k range refers to the range of optical wavevectors (momentum states) of light that can couple into the enhancement layer through the grating modes, compared to a reflective grating on the substrate side of the device. For any array as discussed throughout, the array parameters may be tuned and/or structures may be designed to broaden the array resonance in order to widen the range of angle/wavelength combinations suitable for PIP coupling. That is, the PIP may be coupled through the grating and/or a plasmon lattice resonance mode called a PSLR (plasmon surface lattice resonance) mode, which may excite surface plasmons in the enhancement layer. The PSLR modes may be plasmon mediated collective resonance modes due to the superposition of diffracted light in-plane to the ordered nano particle arrays deposited on the enhancement layer. The in-coupling angle and wavelength may depend on the grating/PSLR mode. In some embodiments, the plasmon modes excited through the grating and/or PSLR modes may be different in energy from the SPR modes generated by the direct coupling of light.

To efficiently convert propagating surface plasmon energy to photons, any number of outcoupling layers may be used. One outcoupling layer that has shown efficient outcoupling is a nanoparticle based plasmon outcoupling scheme, as described above. In an embodiment, the outcoupling layer may include metal or dielectric nanoparticles 1-1000 nm in size, more preferably 50-200 nm in size, and may be separated from the enhancement layer by a specific distance determined by a spacer layer, although embodiments of the present invention recognize that a spacer layer is not required. The thickness of this spacer layer can range from 0-500 nm, and more preferably 0-70 nm. The outcoupling layer may benefit from a planar enhancement layer to improve plasmon propagation length to increase the number of interactions with the nanoparticles, thereby increasing scattering efficiency. In the case where a corrugated reflector layer is used, and it is undesired to have the whole stack corrugated, a planarization layer may be incorporated into the stack above the corrugated reflector layer, as described above. This may include solution processed layers, such as the hole injection layer PEDOT:PSS, or a thermally evaporated, solution processed, or printed layer that may be raised above its glass transition temperature to planarize the corrugation. The planarization layer may play an active role in the device, such as charge transport, optical effects, or the like or may be electrically inactive, (e.g., an insulator).

In an embodiment, the efficiency with which photons may excite surface plasmons may depend on the refractive index of the OLED stack, in other words the layers within the OLED between the first electrode and the second electrode. In an embodiment, the efficiency with which photons may excited surface plasmons may depend on effective refractive index of the layers surrounding the enhancement layer, as can be modified using the porous spacer layer and/or porous overlayer, discussed below. In one embodiment, the effective refractive index of the OLED stack (i.e. the layers within the OLED between the first electrode and the second electrode) may range from 1 to 5, with plasmon coupling efficiency enhanced more preferably for effective refractive index values above 1.5, even more preferably for effective refractive index values above 2. In addition to materials engineering, such refractive index values can be achieved via semiconductor dilution.

An emissive material, such as a phosphor, fluorophore, perovskite, quantum dot, TADF (thermally activated delayed fluorescence), or the like, may also be used to absorb photons and re-emit them at a preferred angle for PIP coupling. In this way, emitters may be used as a photon redirecting element. The emissive redirecting element may be located within the device stack or outside of it, even on the opposite side of the substrate from the device stack. In an embodiment, such as shown in FIG. 3, an additional layer (not shown) may be disposed between the first electrode 330 and the second electrode 340. In an embodiment, such as shown in FIG. 3, an additional layer (not shown) may be disposed on a side of the device outside the OLED stack, in other words either above the second electrode 340 or below the first electrode 330 such that the additional layer is not disposed between the first electrode 330 and the second electrode 340. In any of the embodiments described in FIGS. 3-9, the additional layer may be disposed between the first electrode 330 and the second electrode 340 or the additional layer may be disposed on a side of the device outside the OLED stack, in other words either above the second electrode 340 or below the first electrode 330 such that the additional layer is not disposed between the first electrode 330 and the second electrode 340. The additional layer may comprise an emissive material which may absorb photons and re-emit them a preferred angle for PIP coupling.

In the embodiments of the disclosed subject matter shown in FIGS. 4-9, a device may include a substrate (e.g., 410, 510, etc.), and an enhancement layer may be disposed over the substrate. In an embodiment, the substrate of the device may be at least semi-transparent or fully opaque. In some embodiments, the substrate may be transparent, where at least 30% of light within the visible spectrum may pass through the substrate. In some embodiments, the substrate may be non-transparent, where less than 10% of light within the visible spectrum may pass through the substrate. In an embodiment, the enhancement layer may be an electrode, as discussed above. In some embodiments, the enhancement layer can be a metal, which may be semi-transparent. In any of the embodiments described above, reflector layer (e.g., 412, 512, 612, etc.) may be configured such that at least a portion of light capable of being reflected by the reflector layer is reflected at an angle different than an angle the light is received. In some embodiments, the reflector layer is configured such that at least a portion of light capable of being reflected by the reflector layer is reflected at an angle that causes the portion of light to be incident upon the enhancement layer at 45 degrees+/−15 degrees, +/−10 degrees, +/−5 degrees, +/−3 degrees, and/or +/−1 degree. In some embodiments, at least a portion of light capable of being reflected by the reflector layer may be non-specular reflection. Specular reflection refers to the reflection of light from a smooth surface where all parallel rays of light bounce off at the same angle, creating a clear, mirror-like image, while non-specular reflection (also called diffuse reflection) may occur when light hits a surface and scatters in various directions, (i.e., scattering light in many directions). The reflector may be a photonic crystal, a metal, a dielectric, a distributed Bragg reflector (DBR), or any combination thereof. The light reflection from the reflector layer may be specular or diffusive. For specular reflection, the angle of incidence of the light beam incident on the reflector layer may be equal to the angle of reflection, where the incident and reflected angles are measured with respect to the surface normal. For diffused reflection, some rays of light in the reflected beam may have an angle of reflection that is different from the incident angle, in addition to the specular rays. For grating structures, the angle of reflection may follow the lattice dispersion relation. That is, the light may be diffracted from the grating. In any of the embodiments described above, the reflector layer may be configured to have periodicity based on a wavelength or range of wavelengths of the light to be reflected. The periodicity of the reflector layer for a particular wavelength may be configured to generate a desired incident angle of reflection to generate a surface plasmon polariton.

The device may include a diffuser layer (e.g., 414, 514, 614, etc.) disposed between the reflector layer and the enhancement layer, such as shown in FIGS. 4-9. In any of the embodiments described above, the diffuser layer may be a grating or a light re-directing element. The reflector layer of the device may be corrugated, such as shown in FIG. 5. The corrugation may be a single dimensional array or may be a two-dimensional array. The corrugation may be periodic (e.g., a periodic array, such as grating having a predetermined pitch, where the array pitch sets the array resonance at normal incidence), quasi-periodic, or aperiodic. A planarization layer may be disposed over the corrugated reflector layer, such as shown in FIG. 5. The planarization layer may include a diffuser layer. In some embodiments, the reflector layer material may not match the material of the enhancement layer. This may be to avoid PIP excitement in the reflector layer itself, which may not have an adjacent outcoupling layer. In one example embodiment discussed above, the enhancement layer may be Ag while the reflector layer is Al to avoid the same PIP conditions, allowing the Al reflector layer to reflect the ideal photon angles for the Ag enhancement layer. In another embodiment, a dielectric reflector layer may be used to avoid these parasitic losses. In a similar fashion, dielectric or metal gratings may be used for the same purpose.

In some embodiments, the enhancement layer 940 of the device may be corrugated, such as shown in FIG. 9. As described above, the corrugation may be a single dimensional array or may be a two dimensional array in the specification. The corrugation may be periodic (e.g., a periodic array, such as grating having a predetermined pitch, where the array pitch sets the array resonance at normal incidence), quasi-periodic, or aperiodic. The enhancement layer may include a grating that is disposed on a side of the enhancement layer that faces the emissive layer of the OLED. The device may include an emissive redirecting element disposed within the OLED stack, or disposed over one of the sides of the OLED stack.

In some embodiments, the reflector layer of the device may be disposed below the substrate, such as shown in FIGS. 6-8. The reflector layer may be configured to have periodicity based on wavelength or range of wavelengths of the light to be reflected. The periodicity of the reflector layer for a particular wavelength will generate a desired incident angle of reflection to generate a surface plasmon polariton. As described above, the reflector layer may be a photonic crystal, a metal, a dielectric, a distributed Bragg reflector (DBR), or any combination thereof.

The device shown in FIGS. 4-9 may include a diffuser layer disposed between the reflector layer and the enhancement layer. The reflector layer of the device may be corrugated. The device may include a planarization layer that is disposed over the corrugated reflector layer. The planarization layer of the device may include a diffuser layer. The diffuser layer may be a grating or a light re-directing element. The device may include a transparent electrode disposed over the substrate. The transparent electrode may be for example, a transparent anode. The enhancement layer of the device shown in FIGS. 4-9 may be corrugated. As described above, the corrugation may be a single dimensional array or may be a two dimensional array. The corrugation may be periodic (e.g., a periodic array, such as grating having a predetermined pitch, where the array pitch sets the array resonance), quasi-periodic, or aperiodic. The enhancement layer of the device may include a grating that is disposed on a side of the enhancement layer that faces the emissive layer of the OLED. The device may include an emissive redirecting element disposed within the OLED stack, or disposed over one of the sides of the OLED stack.

Plasmonic OLEDs incorporating outcoupling layers may utilize a spacer layer to spatially separate the wavelength-sized or sub-wavelength sized features (e.g., nanoparticles) from the enhancement layer. In some embodiments, the spacer layer may be a dielectric spacer layer. The outcoupling resonance of the outcoupling layer is determined, in part, by the refractive index of the spacer layer. Therefore, tuning the refractive index of the spacer layer, through porosity or the introduction of materials with varying refractive index, is desirable. Embodiments of the disclosed subject matter provide plasmonic OLEDs where the spacer layer is porous (i.e., has pores) and/or has voids that may be filled with one or materials having varying refractive indices. The one or more materials may cause the bulk refractive index of the spacer layer to be modified as compared to the refractive index of a spacer layer that is a single neat material.

Plasmonic OLEDs incorporating outcoupling layers may utilize an overlayer disposed over the wavelength-sized or sub-wavelength sized features (e.g., nanoparticles). The outcoupling resonance of the outcoupling layer is determined, in part, by the refractive index of the overlayer. Therefore, tuning the refractive index of the outcoupling layer, through porosity or the introduction of materials with varying refractive index, is desirable. Embodiments of the disclosed subject matter provide plasmonic OLEDs where the outcoupling layer is porous (i.e., has pores) and/or has voids that may be filled with one or materials having varying refractive indices. The one or more materials may cause the bulk refractive index of the outcoupling layer to be modified as compared to the refractive index of an outcoupling layer that is a single neat material.

It should be noted, that the refractive index of the material may be specific to a material or may also be referred to as a “bulk” refractive index. As used in the art, the “bulk” refractive index refers to the refractive index of a material or combination of materials measured in bulk form. The refractive index of a material is often expressed in the form n+ik, where n and k represent the real and imaginary part of the refractive index, respectively. Because refractive index is dependent on wavelength, most generally the refractive index can be described as n(λ)=n(λ)+ik(λ).

The refractive index of a material can be measured using a neat solid or a continuous thin film of the material that has a spatial extent at least 10 times the wavelength of light used to measure the index of refraction. For example, the refractive index of a material can be measured using variable angle ellipsometry on a thin film deposited on a silicon wafer, where the film of material to be characterized is 100-500 nm thick. The measured may be done using white light that contains wavelengths from 200 nm to 1600 nm. For this measurement, the lateral extent of the thin film should be larger than 10 micrometers to interrogate the bulk refractive index.

A material also may be described by its dielectric constant ε(ω)=ε₁(ω)+iε₂ (ω), but at optical frequencies the most common convention is to utilize the refractive index as described above. Furthermore, the “bulk refractive index” is also used to describe various regions since the interaction of electromagnetic waves with the medium is most important. For regions that are only composed of one material, using the single physical material would be as effective of a description. However, for materials that are alloys or mixtures with physical components smaller than the wavelength of light that may not be uniformly dispersed, the refractive index of the bulk material as described above is a more precise optical definition of such regions compared to the material composition of the region(s).

It should be noted that embodiments described herein, in reference to a porous spacer layer and/or overlay are not strictly limited to plasmonic devices. Embodiments described herein may be applicable to any OLED device that includes an outcoupling layer with wavelength-sized or sub-wavelength sized features (e.g., nanoparticles). For example, in an OLED device that includes an anode, a cathode, and an organic layer disposed between the anode and the cathode, an outcoupling layer may be disposed over the anode and the cathode. Embodiments of the present invention envision that the outcoupling layer may be disposed on the anode side of the OLED, the cathode side of the OLED, or both. Here, the outcoupling layer may include, but is not limited to, a spacer layer, wavelength-sized or sub-wavelength sized features (e.g., nanoparticles), and/or an overlayer. Light is generated from the organic layer and as the light transmits through the anode or the cathode and subsequently transmits through the outcoupling layer, by modifying the bulk refractive index of the spacer layer and/or overlayer through the inclusion of a plurality of pores within the spacer layer and/or overlayer or by disposing a material within the pores of the porous spacer layer and/or overlayer, the emission characteristics of the transmitted light may be modified when the light exits the outcoupling layer. In an embodiment, at least 5%, 10%, 25%, 50%, and/or 100% of the plurality of nanoparticles may be disposed within the plurality of pores that causes at least some of the plurality of nanoparticles to tilt, wherein the tilt may be configured to have a flat face of at least one nanoparticle not be parallel to a flat side of the spacer layer, the overlayer, or both.

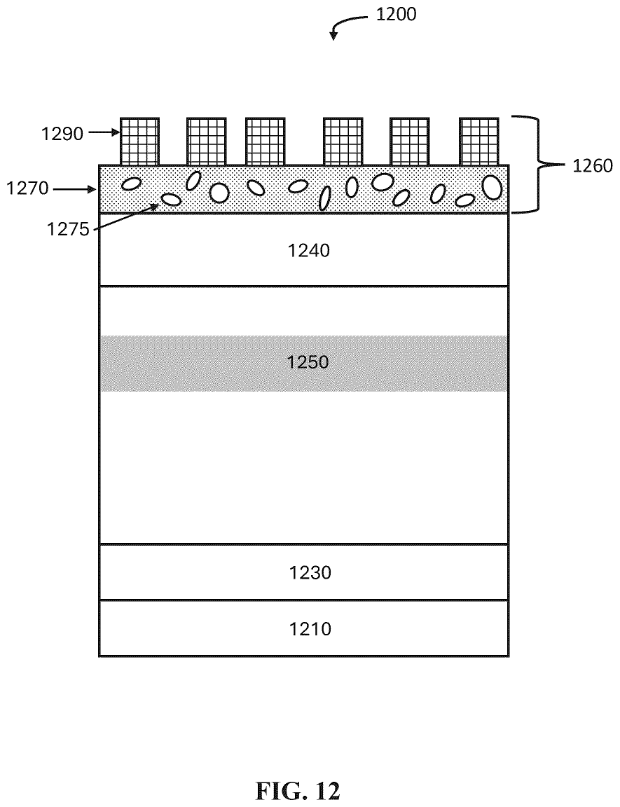

An example of a plasmonic OLED 1200 having a porous spacer layer 1270 is shown in FIG. 12. The plasmonic OLED includes a substrate 1210, a first electrode 1230, a second electrode 1240, and an outcoupling layer 1260. Here, outcoupling layer includes a spacer layer 1270 and a plurality of nanoparticles 1290. At least a portion of the organic layer 1250 is placed within a threshold distance of the enhancement layer, here the second electrode 1240 functions as an enhancement layer, as described herein, and the plasmon energy may be subsequently converted to light by the outcoupling layer 1260, of which the spacer layer 1270 is one part, however embodiments of the present invention do not require an enhancement layer. In some embodiments, the spacer layer 1270 may be a dielectric material. In some embodiments, it is preferable that the refractive index of the spacer layer 1270 be low, i.e., as close to air (n=1) as possible. This may be achieved by introducing porosity into the spacer layer, such as having pores 1275 surrounded by the material of the spacer layer 1270 that form a vacuum. In an alternative embodiment, a portion of the pores 1270 may be filled with an additional material.

Porosity may be introduced to the spacer layer 1270 using one or more methods. One method may be to introduce a material, such as polystyrene nanospheres or beads, into the spacer layer 1270, and then subsequently remove nanospheres or beads by using a solvent, etching, or other means. The pores 1275 may be overcoated with a subsequent layer that does not fill in or completely fill in the pores. In an alternative embodiment, the nanospheres or other foreign material are not removed, and the spacer layer 1270 may have an effective refractive index that blends the intrinsic refractive index with the volume fraction of the foreign material. The polystyrene beads or foreign material may be formed into a random arrangement, a quasi-periodic arrangement, and/or a periodic arrangement like a grating or an array. This may include hexagonal, hexagonal close-packed, square, rectangular, chirped, bullseye, and/or other array patterns. The beads may form a self-assembled monolayer, and/or may be guided into an arrangement via nanoimprint lithography or by using another suitable method.

Some materials may be engineered to grow in a porous fashion, such as silicon dioxide, which may be grown with a nanoscale or mesoscale porosity. Materials deposited via vapor thermal evaporation may have porosity when deposited at an angle relative to the substrate. Similar techniques can be applied to more refractory materials if a more directional deposition is used such as e-beam (electron beam) deposition or using an inductive source to heat the refractory material. In some embodiments, porosity may be achieved in the spacer layer 1270 at the nanoscale in molecular thin films by growing a molecular film naturally to introduce pores 1275. Certain molecular films may achieve this via surface roughness introducing voids at the nanoscale, or by aggregation of molecular clusters, or by surface de-wetting. Fluorinated molecules may possess this property. The surface roughness may vary, but may be greater than 1 nm, greater than 10 nm, and/or greater than 100 nm, where the size of the pores 1275 may scale with the roughness. Certain deposition methods, such as substrate temperature control, rate, angle of the substrate with respect to the deposition plume, and the like, may be implemented to tune the level of roughness and/or porosity of the molecular film.

In this arrangement, the pores 1275 may be typically surrounded by the spacer layer 1270 to form a vacuum. Other than at the surfaces of the spacer layer 1270, the pores 1275 with refractive index n₂ may be entirely surrounded by the spacer layer 1270 with refractive index n₁. The pores 1275 may have air (i.e., n₂=1) or may include some other material (e.g. a dielectric material) with a different refractive index. In one embodiment, there may be more than one material or refractive index existing inside the spacer layer 1270. That is, the pores 1275 may not all have the same refractive index value. In some embodiments, the pores 1275 may be filled with nitrogen, argon, an inert gas, and/or a gas containing a lower concentration of oxygen and water than air which may improve shelf stability of a device. In certain applications, it may be desirable to have the pores 1275 filled with a refractive index material greater than 1, for example, if a high refractive index spacer layer 1270 is desired. However, the pure form of the high refractive index material may be unstable, not easy to process, manufacture, and/or deposit, or may dissolve upon exposure to solvent in a subsequent processing step, such as upon deposition of colloidal nanoparticles atop the spacer layer. These pores 1275 may be subsequently overcoated to prevent exposure to such processes. In some embodiments, the refractive index of the pores 1275 may be n<2, n<1.5, and/or n<1.3.

After the pores 1275 are created, they may be overcoated with a deposition. For example, an atomic layer deposition (ALD), chemical vapor deposition (CVD), and the like may be used to provide structural and/or mechanical stability to the film. This may include relieving stress or strain built into the porous layer or otherwise manipulating these parameters to reach desired properties for subsequent layer deposition or device application, such as flexible or rollable displays.

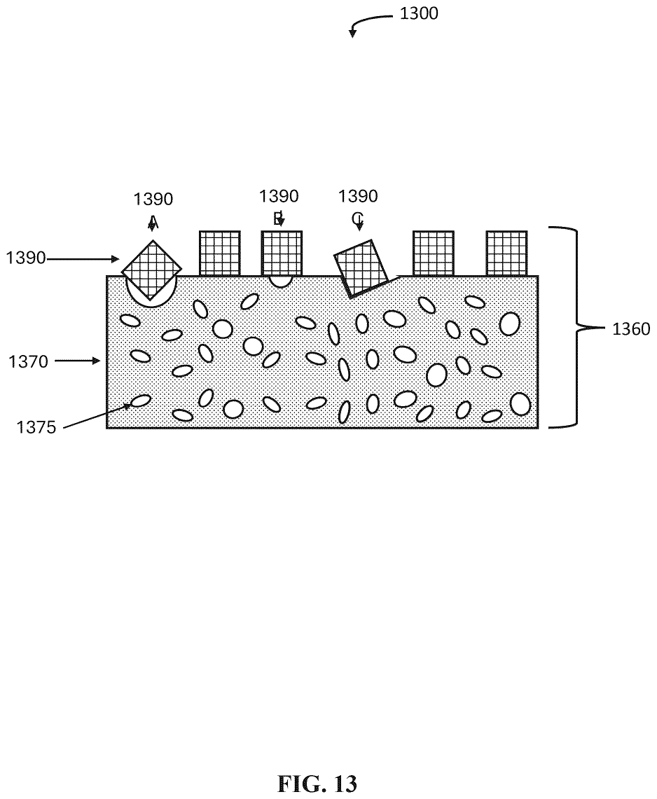

As shown in FIG. 13, in an embodiment, the outcoupling layer includes a spacer layer 1370, a plurality of nanoparticles 1390 (i.e. 1390A, 1390B, and 1390C), and a plurality of pores 1375. Here, the pores 1375 may be located away from the interface of the spacer layer 1370 (i.e., at least the top, but possibly also the bottom plane of the film) to allow for a flat surface for the subsequent nanoparticles 1390 to be disposed on and provide a well-defined separation distance to the enhancement layer. Pores that poke through the top plane of the spacer layer may cause the nanoparticles to tilt, as shown by nanoparticle 1390A and 1390C. Even if the pores 1375 do poke through the top plane of the spacer layer, the likelihood of tilted nanoparticles may be reduced if the pore 1375 maximum cross-sectional dimension of the pore and/or the cross section of the pore as it crosses the top plane of the spacer layer has a dimension in a plane of the surface that is. In an embodiment, the tilt may be relative to the flat face of the nanoparticle, as shown by nanoparticle 1390B.

In an embodiment, at least one pore 1375 of the plurality of pores 1375 has a maximum cross-sectional dimension, wherein the maximum cross-sectional dimension is selected from the group consisting of: less than 50% of a size of a flat face of a nanoparticle 1390 of the plurality of nanoparticles 1390, less than 30% of the size of the flat face of the nanoparticle 1390 of the plurality of nanoparticles 1390, and less than 10% of the size of the flat face of nanoparticle 1390 of the plurality of nanoparticles 1390. In an embodiment, at least one pore 1375 of the plurality of pores 1375 that crosses a surface of the spacer layer 1370 has a first dimension in a plane of the surface, wherein the first dimension is selected from the group consisting of: greater than 50% of a size of a flat face of a nanoparticle 1390 of the plurality of nanoparticles 1390, greater than 70% of the size of the flat face of the nanoparticle 1390 of the plurality of nanoparticles 1390, and greater than 90% of the size of the flat face of the nanoparticle 1390 of the plurality of nanoparticles 1390.

In an embodiment, it may be desirable to tilt the nanoparticles 1390 by having them partially fall into the pores 1375. For example, this may be done to form a desired emission profile, such as a certain color shift and/or an intensity versus angle. This may help achieve a desired nanoparticle orientation, such as cubes oriented with a corner facing downwards, such as shown by nanoparticle 1390A or nanoparticle 1390C of FIG. 13. In an embodiment, at least one pore 1375 of the plurality of pores 1375 that crosses a surface of the spacer layer 1370 has a first dimension in a plane of the surface, wherein the first dimension is selected from the group consisting of: greater than 50% of a size of a flat face of a nanoparticle 1390 of the plurality of nanoparticles 1390, greater than 70% of the size of the flat face of the nanoparticle 1390 of the plurality of nanoparticles 1390, and greater than 90% of the size of the flat face of the nanoparticle 1390 of the plurality of nanoparticles 1390. In an embodiment, at least one pore 1375 of the plurality of pores 1375 has a maximum cross-sectional dimension, wherein the maximum cross-sectional dimension is selected from the group consisting of: greater than 50% of a size of a flat face of a nanoparticle 1390 of the plurality of nanoparticles 1390, greater than 70% of the size of the flat face of the nanoparticle 1390 of the plurality of nanoparticles 1390, and greater than 90% of the size of the flat face of the nanoparticle 1390 of the plurality of nanoparticles 1390.

In an embodiment where the pore 1375 first dimension and/or the maximum cross-sectional dimension of the pore as it crosses the top plane of the spacer layer is of a size that is likely to cause the particle to at least partially fall into the pore, including up to approximately 100% the size of the nanoparticle, the pore shape may be configured such that when the nanoparticle falls into the pore, it is oriented in some preferred way, as shown with nanoparticle 1390C shown in FIG. 13.

As the volume fraction of pores increases toward unity, the effective refractive index of the spacer layer may approach that of the pore material. Practical considerations, such as mechanical stability, may place an upper limit on the pore volume fraction. In an embodiment, the pore material may occupy greater than 20%, greater than 50%, and/or greater than 70% of the volume fraction of the spacer layer. In other words, the pore material may be greater than 20%, greater than 50%, and/or greater than 70% of the volume of the spacer layer.

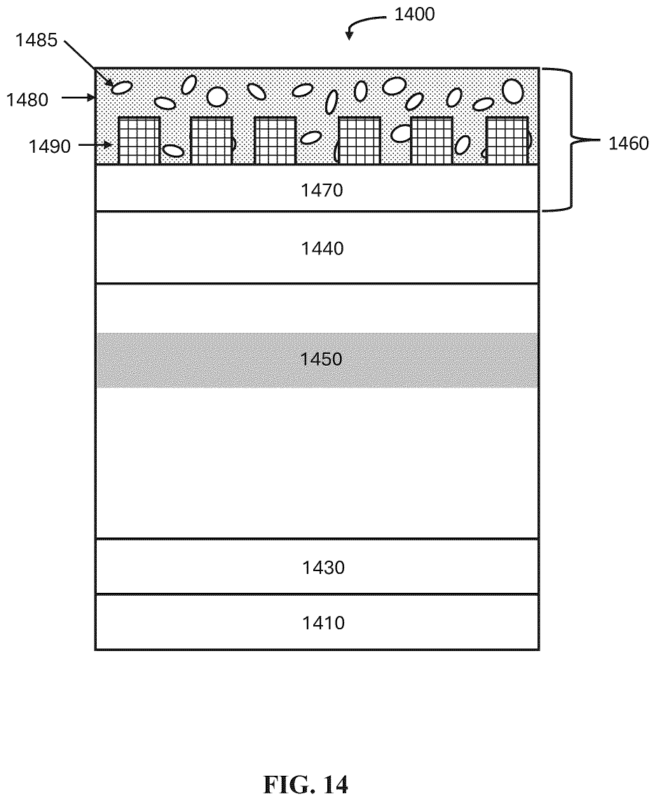

An example of a plasmonic OLED 1400 having a porous overlayer 1480 is shown in FIG. 14. The plasmonic OLED includes a substrate 1410, a first electrode 1430, a second electrode 1440, and an outcoupling layer 1460. Here, outcoupling layer includes a spacer layer 1470, an overlayer 1480 which includes a plurality of pores 1485, and a plurality of nanoparticles 1490. At least a portion of the organic layer 1450 is placed within a threshold distance of the enhancement layer, here the second electrode 1440 functions as an enhancement layer, as described herein, and the plasmon energy may be subsequently converted to light by the outcoupling layer 1460, however embodiments of the present invention do not require an enhancement layer. In some embodiments, the overlayer 1480 may be a dielectric material. In some embodiments, it is preferable that the refractive index of the overlayer 1480 may be low, i.e., as close to air (n=1) as possible. This may be achieved by introducing porosity into the overlayer 1480, such as having pores 1485 surrounded by the material of the overlayer 1480 that form a vacuum. In an alternative embodiment, a portion of the pores 1485 may be filled with an additional material. It should be noted, advantages described above in reference FIG. 12 are applicable to embodiments of FIG. 14. In other words, methods of forming pores 1275 of FIG. 12 may be applicable to formation of pores 1485 of FIG. 14. Additionally, advantages described above in reference to FIG. 12 related to modifying the bulk refractive index of spacer layer 1270 are applicable as well to the modified bulk refractive index of overlayer 1480. These advantages may be envisioned through the inclusion of an additional material within the pores 1475 or through the pores 1485 being filled with nitrogen, argon, an inert gas, and/or a gas containing a lower concentration of oxygen and water than air similar to the embodiments applied to the spacer layer 1270 of FIG. 12. In other words, all methods, embodiments, and advantages applicable to the spacer layer 1270 of FIG. 12 are applicable to the overlayer 1480 of FIG. 14.

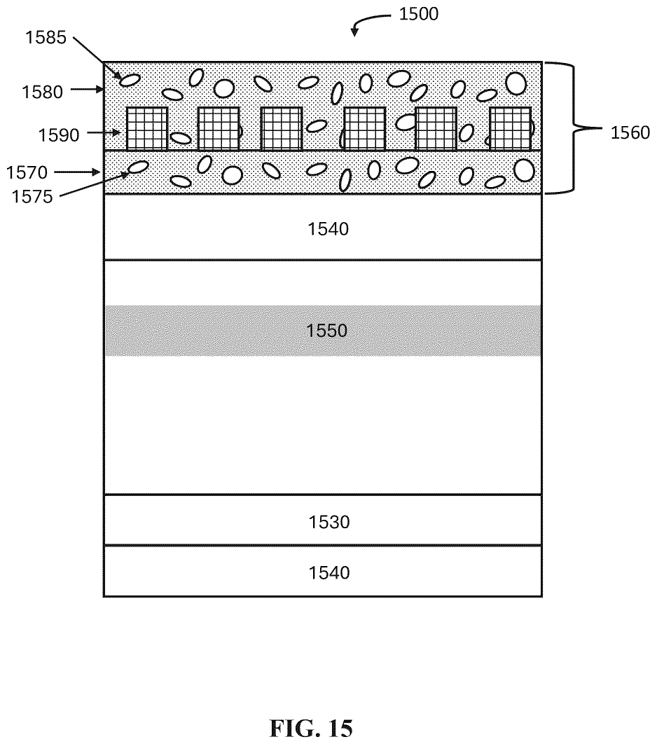

An example of a plasmonic OLED 1500 having a porous spacer layer 1570 and porous overlayer 1580 is shown in FIG. 15. The plasmonic OLED includes a substrate 1510, a first electrode 1530, a second electrode 1540, and an outcoupling layer 1560. Here, outcoupling layer includes a spacer layer 1570 which includes a plurality of pores 1575, an overlayer 1580 which includes a plurality of pores 1585, and a plurality of nanoparticles 1590. At least a portion of the organic layer 1550 is placed within a threshold distance of the enhancement layer, here the second electrode 1540 functions as an enhancement layer, as described herein, and the plasmon energy may be subsequently converted to light by the outcoupling layer 1560, however embodiments of the present invention do not require an enhancement layer. In some embodiments, the spacer layer 1570 may be a dielectric material. In some embodiments, the overlayer 1580 may be a dielectric material. In some embodiments, it is preferable that the refractive index of the spacer layer 1580 and/or overlayer 1580 may be low, i.e., as close to air (n=1) as possible. One way this may be achieved by introducing porosity into the spacer layer 1570, such as having pores 1575 surrounded by the material of the spacer layer 1570 that form a vacuum. In an alternative embodiment, a portion of the pores 1575 may be filled with an additional material. One way this may be achieved by introducing porosity into the overlayer 1580, such as having pores 1585 surrounded by the material of the overlayer 1580 that form a vacuum. In an alternative embodiment, a portion of the pores 1585 may be filled with an additional material. It should be noted, advantages described above in reference FIGS. 12 and 14 are applicable to embodiments of FIG. 15. In other words, methods of forming pores 1275 of FIG. 12 and pores 1485 of FIG. 14 may be applicable to formation of pores 1575 and pores 1585 of FIG. 15. Additionally, advantages described above in reference to FIG. 12 related to modifying the bulk refractive index of spacer layer 1270 and advantages described above in reference to FIG. 14 related to modifying the bulk refractive index of overlayer 1480 are applicable as well to the embodiments of device 1500 that include both the modified bulk refractive index of spacer layer 1570 and overlayer 1580. These advantages may be envisioned through the inclusion of an additional material within the pores 1575 and/or pores 1585 or through the pores 1575 and/or pores 1585 being filled with nitrogen, argon, an inert gas, and/or a gas containing a lower concentration of oxygen and water than air similar to the embodiments applied to the spacer layer 1270 of FIG. 12 and overlayer 1480 of FIG. 14. In other words, all methods, embodiments, and advantages applicable the spacer layer 1270 of FIG. 12 and overlayer 1480 of FIG. 14 are applicable to the spacer layer 1570 and overlayer 1580 of FIG. 15.

In any of the embodiments described above in reference to FIG. 14 or FIG. 15, similar to FIGS. 12 and 13, at least one pore (e.g. 1485, 1575, 1585) of the plurality of pores (e.g. 1485, 1575, 1585) has a maximum cross-sectional dimension, wherein the maximum cross-sectional dimension is selected from the group consisting of: less than 50% of a size of a flat face of a nanoparticle of the plurality of nanoparticles, less than 30% of the size of the flat face of the nanoparticle of the plurality of nanoparticles, and less than 10% of the size of the flat face of nanoparticle of the plurality of nanoparticles. In an embodiment, at least one pore (e.g. 1485, 1575, 1585) of the plurality of pores (e.g. 1485, 1575, 1585) that crosses a surface of the spacer layer (e.g. 1570) and/or overlayer (e.g. 1570, 1580) has a first dimension in a plane of the surface, wherein the first dimension is selected from the group consisting of: greater than 50% of a size of a flat face of a nanoparticle of the plurality of nanoparticles, greater than 70% of the size of the flat face of the nanoparticle of the plurality of nanoparticles, and greater than 90% of the size of the flat face of the nanoparticle 1390 of the plurality of nanoparticles.

In any of the embodiments described above in reference to FIG. 14 or FIG. 15, similar to FIGS. 12 and 13, at least one pore (e.g. 1485, 1575, 1585) of the plurality of pores (e.g. 1485, 1575, 1585) has a first dimension in a plane of the surface, wherein the first dimension is selected from the group consisting of: greater than 50% of a size of a flat face of a nanoparticle of the plurality of nanoparticles, greater than 70% of the size of the flat face of the nanoparticle of the plurality of nanoparticles, and greater than 90% of the size of the flat face of the nanoparticle of the plurality of nanoparticles. In an embodiment, at least one pore of the plurality of pores has a maximum cross-sectional dimension, wherein the maximum cross-sectional dimension is selected from the group consisting of: greater than 50% of a size of a flat face of a nanoparticle of the plurality of nanoparticles, greater than 70% of the size of the flat face of the nanoparticle of the plurality of nanoparticles, and greater than 90% of the size of the flat face of the nanoparticle of the plurality of nanoparticles.

As described above in reference to FIGS. 12-15, one or more of the pores of the spacer layer and/or overlayer may be filled with one or more materials having different refractive indices. The porous spacer layer and/or porous overlayer may include a first material having a first refractive index. One or more of the plurality of pores of the porous spacer layer and/or porous overlayer shown in FIGS. 12-15 may be filled with at least a second material having a second refractive index that is different than the first refractive index of the first material. The porous spacer layer and/or porous overlayer of the device shown in FIGS. 12-15 may include a first material having a first refractive index, where one or more of the plurality of pores of the porous spacer layer and/or porous overlayer may be at least partially filled with at least a second material having a second refractive index. The porous spacer layer and/or porous overlayer may have a total refractive index based on the first refractive index and the second refractive index. In some embodiments, the first material and/or the second material may comprise at least a dielectric material.

In an embodiment, the vacuum of one or more of the plurality of pores of the porous spacer layer and/or porous overlayer such as shown in FIGS. 12-15 may be filled with air, nitrogen, argon, inert gas, a gas having a lower concentration of oxygen and water than air, and/or dielectric material. Inert gases and ones that contain low concentrations of oxygen and water may be preferable to increase device shelf stability. In other words, to increase device lifetime. One or more of the plurality of pores may have the same refractive index and/or a different refractive index. A refractive index (n) of one or more of the plurality of pores of the device may be n<2, n<1.3, and/or n<1.5.

Embodiments described herein may be found in devices that have pixels that include one or more sub-pixels. Embodiments described herein may be a device in at least one of the one or more sub-pixels. In a first embodiment, at least one of the sub-pixels may be in a side-by-side (SBS) architecture. In a SBS architecture, at least one or more emissive layers of each sub-pixel in the pixel may be different than another sub-pixel in the pixel. In a SBS architecture, at least one or more outcoupling layers of each sub-pixel may be different than an outcoupling layer of another sub-pixel in the pixel. These differences may lead to different light emission characteristic for each sub-pixel. Generally, a “Red” sub-pixel will have a red emissive layer and the red emissive layer emits red light and the sub-pixel emits red light. In an embodiment, there may be no color filter or color altering layer in a SBS architecture, although this is not a requirement and a color filter or color altering layer may be used. In a second embodiment, at least one of the sub-pixels may be in a stacked architecture. In a stacked architecture, at least one or more emissive layer is shared between two or more sub-pixels in the pixel. Generally, this is used in a white plus color filter/color altering layer architecture, where the emissive layers in the pixel produce “white” light and different color filter/color altering layer arrangements are used for sub-pixels in the pixel to produce a desired color. For example, the stack may produce “white,” a first sub-pixel may have a red color filter/color altering layer, so the first sub-pixel may produce red light and a second sub-pixel may have a green color filter/color altering layer, so the second sub-pixel may produce green light. Any color filtering/altering may be used to produce any color light. Additionally, the stack does not necessarily need to produce a “white” light and can produce any color light. Devices may be made that are a mixture of both SBS and stack architecture to produce pixel/sub-pixel designs that include some or all of the embodiments described. Embodiments of the present invention may be included in one or more of a SBS or stacked pixel/sub-pixel designs.

Additionally, any of the devices herein may replace either the first electrode or the second with a charge generation layer. Here, a second device (or more), similar or different to the devices to the first device and/or similar or different to devices described in embodiments herein, may be placed in series with the first device in order to form a tandem device. In a tandem device, the first device may have an anode or a cathode on a first side of the first device farther from the second device, between the first and second device may be a charge generation layer which replaces the anode or cathode, and the second device may have either an anode or cathode (whichever was not found in the first device) on a second side of the of the second device farther from the first device.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An organic light emitting device (OLED) comprising:
a substrate;
a first electrode disposed over the substrate;
a second electrode disposed over the first electrode; and
an organic layer disposed between the first electrode and the second electrode, wherein the organic layer comprises an emitter material.

2. (canceled)

3. The OLED of claim 1, wherein the organic layer is configured to generate one or more excited states, wherein the OLED comprises a plasmonic material supporting a plasmon polariton mode, and wherein the OLED is configured to transfer at least 5% of energy from said one or more excited states to said plasmon polariton mode.

4. The OLED of claim 3, wherein at least 5% of energy transferred to the plasmon polariton mode is converted into photons in free space.

5. The OLED of claim 3, wherein the first electrode, second electrode, or an additional layer disposed next to the first electrode or the second electrode is configured as an enhancement layer comprising the plasmonic material.

6. The OLED of claim 5, wherein the emitter material has a non-radiative rate constant k_{NR}, a radiative rate constant k_{R}, an incoupling rate constant due to the enhancement layer kₚ, and a radiative rate constant due to the enhancement layer k_{R}_{ₚₗₐₛₘₒₙ}, and the enhancement layer is provided no more than a threshold distance away from the organic layer, so that the inequality of
$$\frac{{k}_{{R}_{p l asmon}}}{{k}_{P}} < \frac{{k}_{R}}{{k}_{N R}}$$
is always true.

7. The OLED of claim 6, wherein the wavelength-sized or sub-wavelength sized features comprise a plurality of nanoparticles.

8.-9. (canceled)

10. The OLED of claim 1, wherein the material at least partially surrounding the plurality of pores has a first refractive index and the plurality of pores that are at least partially surrounded by the material are filled with at least a second material, wherein the second material has a second refractive index, and wherein the first refractive index is different from the second refractive index.

11. (canceled)

12. The OLED of claim 10, wherein the spacer layer, the overlayer, or both has a bulk refractive index based on the first refractive index and the second refractive index.

13. The OLED of claim 1, wherein the spacer layer, the overlayer, or both comprise at least one dielectric material.

14. The OLED of claim 1, wherein at least one pore of the plurality of pores is filled with at least one selected from a group consisting of: air, nitrogen, argon, an inert gas, a gas having a lower concentration of at least one of oxygen or water than air, and dielectric material.

15. The OLED of claim 1, wherein a refractive index (nₚ) of the plurality of pores is selected from the group consisting of: nₚ<2, nₚ<1.5, and nₚ<1.3.

16. The OLED of claim 7, wherein at least 5% of the plurality of nanoparticles are disposed within the plurality of pores that causes at least some of the plurality of nanoparticles to tilt, wherein the tilt is configured to have a flat face of at least one nanoparticle not be parallel to a flat side of the spacer layer, the overlayer, or both.

17.-21. (canceled)

22. The OLED of claim 1, wherein at least one pore of the plurality of pores that crosses a surface of the spacer layer, the overlayer, or both has a first dimension in a plane of the surface, wherein the first dimension is less than 50% of a size of a flat face of a nanoparticle of the plurality of nanoparticles.

23.-24. (canceled)

25. The OLED of claim 1, wherein at least one pore of the plurality of pores has a maximum cross-sectional dimension, wherein the maximum cross-sectional dimension is less than 50% of a size of a flat face of a nanoparticle of the plurality of nanoparticles.

26.-27. (canceled)

28. The OLED of claim 1, wherein at least one pore of the plurality of pores that crosses a surface of the spacer layer, the overlayer, or both has a first dimension in a plane of the surface, wherein the first dimension is greater than 50% of a size of a flat face of a nanoparticle of the plurality of nanoparticles.

29.-30. (canceled)

31. The OLED of claim 1, wherein at least one pore of the plurality of pores has a maximum cross-sectional dimension, wherein the maximum cross-sectional dimension is greater than 50% of a size of a flat face of a nanoparticle of the plurality of nanoparticles.

32. (canceled)

33. (canceled)

34. The OLED of claim 10, wherein the second material forms at least one selected from a group consisting of: a random arrangement, a quasi-periodic arrangement, a periodic arrangement, a grating, and an array.

35. The OLED of claim 34, wherein the second material is arranged in an array, and the array is a hexagonal array, a hexagonal close-packed array, a square array, a rectangular array, a chirped array, a bullseye array, or a combination thereof.

36. The OLED of claim 10, wherein the second material has a volume fraction of the spacer layer, the overlayer, or both, and wherein the volume fraction is greater than 20%.

37-76. (canceled)

77. The OLED of claim 1, wherein at least a portion of the plurality of pores are fully surrounded by the material to form a vacuum within the portion of the plurality of pores.
